(19) United States
(12) Patent Application Publication
(10) Pub. No.: US 2023/0146688 A1
(43) Pub. Date: May 11, 2023

(54) FUNCTIONAL FILM AND PRODUCTION METHOD OF FUNCTIONAL FILM

(71) Applicant: KONICA MINOLTA, INC., Tokyo (JP)

(72) Inventor: Kazunari TADA, Tokyo (JP)

(73) Assignee: KONICA MINOLTA, INC., Tokyo (JP)

(21) Appl. No.: 18/052,668

(22) Filed: Nov. 4, 2022

(30) Foreign Application Priority Data
Nov. 9, 2021 (JP) 2021-182554

(51) Int. Cl. C23C 14/10; C23C 14/22; C23C 14/58; B01J 21/06; B01J 35/00; B01J 33/00

(52) U.S. Cl. CPC C23C 14/10; C23C 14/221; C23C 14/5873; B01J 21/063; B01J 35/004; B01J 33/00

(57) ABSTRACT

A functional film provided on a base material and having a fine uneven structure on its surface of the functional includes a coating. The coating is a coating film or a coating layer of the fine uneven structure. The coating is on a surface of the base material or a constituent layer and covers at least a bumpy portion or an entire surface of the base material. The fine uneven structure includes bumps and dents whose mutual positional relationship and shape have randomness with no regularity in terms of identity or periodicity and does not generate diffracted light.

### CROSS-REFERENCE TO RELATED APPLICATIONS

The entire disclosure of Japanese Patent Application No. 2021-182554 filed on Nov. 9, 2021 is incorporated herein by reference in its entirety.

### BACKGROUND

### Technological Field

The present invention relates to a functional film and a production method of the functional film. In particular, the present invention relates to a functional film and the like which has excellent characteristics in a high temperature and high humidity environment and can be easily put into practical use at low cost.

### Description of the Related Art

Functional films that utilize a surface microstructure have been proposed. By increasing the surface area of the functional films as much as possible, the functionality can be increased. However, in most cases, the conventional production method of the functional films having microstructures include use of lithography and preparation of a mask, followed by etching. Therefore, it was difficult to put it into practical use in terms of cost.

Also, in terms of properties, the etched surface having no pores (vacancies) at the atomic or molecular size level is the final surface. As a result, it was found that the surface area at the atomic level is reduced, even though nano-level unevenness is created, resulting in poor functional film properties. On the other hand, layers produced by a coating process using the sol-gel method have pores at the atomic or molecular size level that remain relatively intact, but have a problem of being less resistant to rub than films formed by a dry process.

The above functional films include, for example, hydrophilic films, but conventional hydrophilic films are weak under the high temperature and high humidity environment, and have large contact angles due to water containing alkali components, oil, and other contaminants. For example, JP 2015-227904A discloses a technology to form microstructures by etching, but the etched surface is no longer porous due to the removal of atomic or molecular size level unevenness. Therefore, although the initial performance is good, the hydrophilic property deteriorates under the high temperature and high humidity environment.

### SUMMARY

The present invention was made in view of the above problems and circumstances, and its purpose is to provide a functional film and a production method of the functional film that has excellent properties in the high temperature and high humidity environment and can be easily put into practical use at low cost has nano-order unevenness and pores at the atomic or molecular size level.

In the process of examining the causes of the above problems, the inventor of the present invention found that a functional film having a coating layer on a layer having an uneven shape can provide a porous coating layer with a fine uneven structure and excellent properties in the high temperature and high humidity environment, and thus arrived at the present invention.

In addition, when the mutual positional relationship and shape of the plurality of bumps and dents of the fine uneven structure have randomness with no regularity in terms of identity or periodicity to the extent such that no diffracted light occurs, it is possible to provide a functional film that exhibits the effects of improved visibility and good functionality as an optical component, has a porous surface, and has excellent properties in the high temperature and high humidity environment.

In other words, the above problems related to the present invention are solved by the following means.

To achieve at least one of the above-mentioned objects, according to an aspect of the present invention, a functional film provided on a base material and having a fine uneven structure on a surface of the functional film reflecting one aspect of the present invention includes:

a coating that is a coating film or a coating layer of the fine uneven structure, the coating being on a surface of the base material or a constituent layer and covering at least a bumpy portion or an entire surface of the base material, wherein

the fine uneven structure includes bumps and dents whose mutual positional relationship and shape have randomness with no regularity in terms of identity or periodicity and does not generate diffracted light.

To achieve at least one of the above-mentioned objects, according to another aspect of the present invention, a functional film provided on a base material and having a fine uneven structure on a surface of the functional film reflecting one aspect of the present invention includes:

at least one uneven layer; and

a coating that is a coating layer on the uneven layer.

To achieve at least one of the above-mentioned objects, according to another aspect of the present invention, a production method of the functional film reflecting the above aspects of the present invention includes:

forming an unevenness unformed layer on the base material by a dry process.

### BRIEF DESCRIPTION OF THE DRAWINGS

The advantages and features provided by one or more embodiments of the invention will become more fully understood from the detailed description given hereinbelow and the appended drawings which are given by way of illustration only, and thus are not intended as a definition of the limits of the present invention, wherein:

FIG. 1 is a cross-sectional schematic diagram showing an example of a basic structure of a functional film of the present invention;

FIG. 2 is a cross-sectional schematic diagram showing an example of a basic structure of a functional film of the present invention;

FIG. 3 is a cross-sectional schematic diagram showing an example of a basic structure of a functional film of the present invention;

FIG. 4A is a process diagram showing an example of a production method of the functional film of FIG. 1;

FIG. 4B is a process diagram showing an example of a production method of the functional film of FIG. 1;

FIG. 4C is a process diagram showing an example of a production method of the functional film of FIG. 1;

FIG. 4D is a process diagram showing an example of a production method of the functional film of FIG. 1;

FIG. 4E is a process diagram showing an example of a production method of the functional film of FIG. 1;

FIG. 4F is a process diagram showing an example of a production method of the functional film of FIG. 1;

FIG. 5A is a process diagram showing an example of a production method of the functional film of FIG. 2;

FIG. 5B is a process diagram showing an example of a production method of the functional film of FIG. 2;

FIG. 5C is a process diagram showing an example of a production method of the functional film of FIG. 2;

FIG. 6 is a cross-sectional schematic diagram showing a structure of a functional film 1 in EXAMPLES;

FIG. 7 is a cross-sectional schematic diagram showing a structure of a functional film 2 in EXAMPLES;

FIG. 8 is a cross-sectional schematic diagram showing a structure of a functional film 3 in EXAMPLES;

FIG. 9 is a cross-sectional schematic diagram showing a structure of a functional film 4 in EXAMPLES;

FIG. 10A is a cross-sectional schematic diagram showing a structure of a functional film 5 in EXAMPLES;

FIG. 10B is a cross-sectional schematic diagram showing a structure of a functional film 5 in EXAMPLES;

FIG. 11A is a cross-sectional schematic diagram showing a structure of a functional film 6 in EXAMPLES;

FIG. 11B is a cross-sectional schematic diagram showing a structure of a functional film 6 in EXAMPLES;

FIG. 12 is a cross-sectional schematic diagram showing a structure of a functional film 7 in EXAMPLES;

FIG. 13A is a cross-sectional schematic diagram showing a structure of a functional film 8 in EXAMPLES;

FIG. 13B is a cross-sectional schematic diagram showing a structure of a functional film 8 in EXAMPLES;

FIG. 14A is a cross-sectional schematic diagram showing a structure of a functional film 9 in EXAMPLES;

FIG. 14B is a cross-sectional schematic diagram showing a structure of a functional film 9 in EXAMPLES;

FIG. 15 is a cross-sectional schematic diagram showing a structure of a functional film 10 in EXAMPLES;

FIG. 16A is a cross-sectional schematic diagram showing a structure of a functional film 11 in EXAMPLES;

FIG. 16B is a cross-sectional schematic diagram showing a structure of afunctional film 11 in EXAMPLES;

FIG. 17A is a cross-sectional schematic diagram showing a structure of afunctional film 12 in EXAMPLES;

FIG. 17B is a cross-sectional schematic diagram showing a structure of afunctional film 12 in EXAMPLES;

FIG. 18A is a cross-sectional schematic diagram showing a structure of a functional film 13 in EXAMPLES;

FIG. 18B is a cross-sectional schematic diagram showing a structure of a functional film 13 in EXAMPLES;

FIG. 19 is a cross-sectional schematic diagram showing a structure of a functional film 14 in EXAMPLES;

FIG. 20 is a cross-sectional schematic diagram showing a structure of a functional film 15 in EXAMPLES;

FIG. 21A is an image of the functional film 1 in EXAMPLES observed by an electron microscope;

FIG. 21B is an image of the functional film 1 in EXAMPLES observed by an electron microscope;

FIG. 22 is an image of the functional film 8 in EXAMPLES observed by an electron microscope;

FIG. 23 is an image of the functional film 9 in EXAMPLES observed by an electron microscope;

FIG. 24 is an image of the functional film 12 in EXAMPLES observed by an electron microscope;

FIG. 25 is an image of the functional film 13 in EXAMPLES observed by an electron microscope;

FIG. 26A is a diagram showing a result of composition analysis of an uppermost layer of the functional film 5 in EXAMPLES;

FIG. 26B is a diagram showing a result of composition analysis of an uppermost layer of the functional film 5 in EXAMPLES;

FIG. 27A is a diagram showing a reflection property of the functional film 10 in EXAMPLES;

FIG. 27B is a diagram showing a reflection property of the functional film 10 in EXAMPLES;

FIG. 28A is a diagram illustrating an anti-fog effect of an anti-fog layer according to the present invention;

FIG. 28B is a diagram illustrating an anti-fog effect of an anti-fog layer according to the present invention;

FIG. 29A is a diagram illustrating an anti-fog effect of an anti-fog layer according to the present invention;

FIG. 29B is a diagram illustrating an anti-fog effect of an anti-fog layer according to the present invention;

FIG. 30A is a diagram illustrating an anti-fog effect of an anti-fog layer according to the present invention;

FIG. 30B is a diagram illustrating an anti-fog effect of an anti-fog layer according to the present invention;

FIG. 31A is an image observed by an electron microscope of a functional film having the anti-fog layer according to the present invention before exposure to etching gas; and

FIG. 31B is an image observed by an electron microscope of a functional film having the anti-fog layer according to the present invention after exposure to etching gas.

### DETAILED DESCRIPTION OF EMBODIMENTS

Hereinafter, one or more embodiments of the present disclosure will be described with reference to the drawings. However, the scope of the present disclosure is not limited to these embodiments or illustrated examples.

The expression mechanism of the effect or action mechanism of the present invention is not clear, but is inferred as follows.

The functional film of the present invention is a functional film having a fine uneven structure on the surface. The fine uneven structure is not formed by etching or sol-gel method, but by covering the surface having a fine uneven structure with a coating (a coating film or coating layer) containing a functional material. Therefore, the functional film does not have the aforementioned disadvantages of the uneven structure produced by the etching or sol-gel method. In addition, since the etching method is not necessarily used in the formation of the fine uneven structure, the functional film can be produced at low cost and easily put into practical use.

In other words, according to the present invention, for example, a coating film or coating layer is provided on at least one uneven layer. Since the coating film or coating layer takes over the unevenness due to the uneven layer, a porous coating film or coating layer is formed that has a nano-order fine uneven structure and atomic size level pores. Thus, a fine uneven structure can be easily formed. In addition, since the uneven layer is covered by the coating film or coating layer, the uneven layer can be fixed, has good adhesion to abase material, and has excellent rub resistance. As a result, the functional film has excellent properties under high temperature and high humidity, and can be put to practical use at low cost.

In particular, when the uneven layer is a particle containing layer, nano-order crystals are formed and fine unevenness is formed. When a coating film or coating layer is further provided on the particle containing layer, a porous coating film or coating layer having atomic size level pores is formed, and hydrophilicity in the high temperature and high humidity environment can be improved. In addition, the adhesion of the particle containing layer is also improved, resulting in excellent rub resistance.

Furthermore, in the present invention, the mutual positional relationship and shape of the plurality of bumps and dents of the fine uneven structure have randomness with no regularity in terms of identity or periodicity to the extent such that no diffracted light occurs. The presence of fine unevenness and the lack of diffracted light can provide the effect of improved visibility and good functionality as an optical component. Furthermore, the functions of the functional film of the present invention, such as hydrophilicity or hydrophobicity, can be enhanced.

That is, when a hydrophilic material is used for the coating film or coating layer of a fine uneven structure, for example, the finer the uneven structure is, that is, the larger the surface roughness is, the larger the specific surface area (the ratio of an area of a rough surface to an area of a flat surface before the uneven structure is formed) is, and the smaller the contact angle on the hydrophilic surface is, which increases the hydrophilicity. On the other hand, when a hydrophobic material is used, the finer the uneven structure is, the larger the contact angle is, which increases the hydrophobicity. Therefore, the function of the functional film, such as hydrophilicity or hydrophobicity, can be enhanced.

Furthermore, when a photocatalytic layer is provided under the coating film or coating layer, for example, due to the porous coating film or coating layer or a gap (atomic size level pores) between bumps and dents adjacent to each other in the fine uneven structure, through which the active chemical species generated by the photocatalyst reaction can pass, the porous structure or the gap can be a pathway connecting the photocatalytic layer and the outermost surface, allowing the photocatalytic effect to be expressed on the surface. As a result, the surface of the functional film can be kept clean, and its hydrophilicity under the high temperature and high humidity environment can be improved.

Pores on the atomic size level, for example, are of a size that allows the active chemical species of the photocatalyst to pass through. When the pores are too small, the active species of the photocatalyst cannot pass through the pores because the pores are clogged under an 85° C. and 85% RH environment. In the same principle, when the pores are too small, the contact angle is deteriorated due to the loss of pores into which water molecules can soak under the 85° C. and 85% RH environment. For example, by forming a layer in a poor vacuum in a dry process, such atomic size level pores can be created. However, because the pores become too small under the 85° C. and 85% RH environment, it is observed that the active chemical species in the photocatalyst cannot pass through the pores and that the contact angle is deteriorated. Furthermore, due to poor vacuum, adhesion and rub resistance are deteriorated even in forming a layer by the dry process.

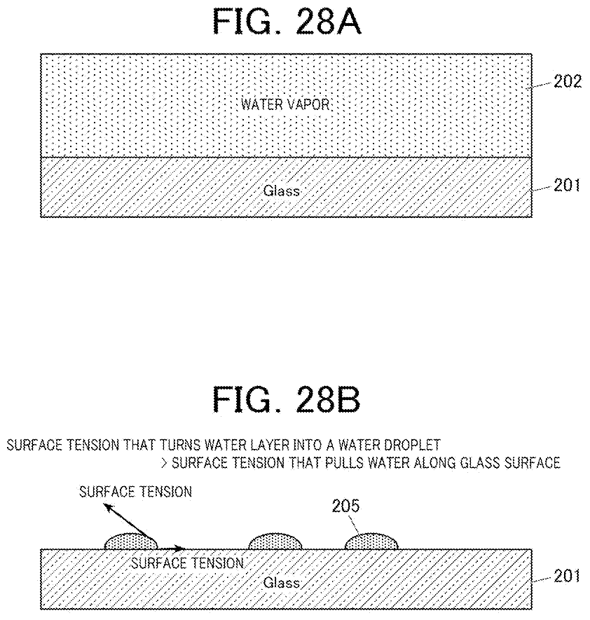

According to the present invention, even though the film is formed by the dry process, the pores at the atomic size level are large enough to prevent clogging of the active chemical species in the photocatalyst even under the 85° C. and 85% RH environment and to prevent degradation of contact angle. It was found that when such nano-order unevenness and atomic-size pores extend over a sufficient thickness (100 nm or more, for example, 200 nm), even anti-fog properties can be imparted. The principle of this anti-fog effect is described later (see FIG. 28A to FIG. 30B).

The expression mechanism of photoinduced hydrophilicity is inferred as follows. When titanium dioxide is used as a photocatalyst, electrons and holes are generated inside the titanium dioxide by electronic excitation in response to UV light irradiation. These electrons and holes react with water and oxygen on the surface to generate various active species such as .OH, O₂⁻, and HO₂*. These active species oxidize and decompose contaminants and bacteria adsorbed on the surface, thereby providing light cleaning and antibacterial functions. Alternatively, when a photocatalytic layer containing titanium dioxide is provided under a layer containing silica (SiO₂), for example, the supply of water molecules from highly water-absorbent silica to titanium dioxide is inferred to cause a structural change that facilitates water adsorption on the titanium dioxide surface upon UV irradiation.

As for the expression mechanism of photoinduced hydrophilicity, see the following non-patent documents.
1) Akira Nakajima, “Surface Science of Hydrophilicity and Water Repellency—Superhydrophilicity, Super Water Repellency and Dynamic Water Repellency”, J. Vac. Soc. Jpn. Vol. 58, No. 11, p. 417-428, 2015
2) Kazuhito Hashimoto and Hiroshi Irie, “Photoinduced Hydrophilic Reaction of Titanium Dioxide Surface,” Surface Science, Vol. 25, No. 5, p. 252-259, 2004

The functional film of the present invention is a functional film provided on a base material and having a fine uneven structure on the surface, and is basically characterized by the following embodiments (A) or (B).

(A) The fine uneven structure has a coating film or coating layer provided on a surface of a base material or a constituent layer(s) and covering at least the bumpy portion or the entire surface, and

the mutual positional relationship and shape of a plurality of bumps and dents of the fine uneven structure have randomness with no regularity in terms of identity or periodicity to an extent such that no diffracted light occurs.

(B) The functional film has at least one uneven layer and a coating layer on the uneven layer.

As an embodiment of the present invention, even in the case of (B) above, the mutual positional relationship and shape of a plurality of bumps and dents of the fine uneven structure preferably have randomness with no regularity in terms of identity or periodicity to an extent such that no diffracted light occurs in terms of the effect of improved visibility, good functionality as an optical component, properties against water, such as hydrophilic or water repellency, and optical properties.

In the fine uneven structure, the arithmetic average roughness Ra of the bumps is preferably in the range of 2 to 50 nm, the maximum height of the bumps is preferably in the range of 10 to 500 nm, and the average diameter of the bumps is preferably in the range of 10 to 1000 nm, in order that the rub resistance and properties of the functional film can be increased.

It is preferred that the coating film or coating layer is a dry-processed layer that is formed by a dry process, and that the bumpy portion or unevenlayer is a dry-processed layer that is formed by a dry process, because it improves adhesion and rub resistance, and allows for easy production of a fine uneven structure and a porous structure.

The solubility of at least one of the compounds constituting the functional film in water at 20° C. is preferably 0.5 g/100 mL or more in that uniformly distributed particles can be easily formed by formation of the layer containing the compound by the dry process followed by exposure to an atmosphere containing moisture.

Apart of the functional film preferably contains an inorganic salt in that a fine uneven structure and a porous structure can be formed. In particular, apart of the functional film preferably contains an alkali metal salt or alkaline earth metal salt in terms of improved resistance to high temperature and high humidity of the hydrophilic property.

The fine uneven structure preferably has a gap between bumps and dents adjacent to each other that is large enough to allow the active chemical species generated by the photocatalyst reaction to pass through the gap, in terms of keeping the surface clean, increasing the surface area, and enhancing the anti-fog and hydrophilic properties.

A photocatalytic layer is preferably provided between the base material and the bumpy portion or the uneven layer so as to express the photocatalytic effect.

The photocatalytic layer preferably contains TiO₂ as a main component in order to have high durability, high photocatalytic effect, high refractive index, and reduced optical reflectance.

The coating film or coating layer is preferably hydrophilic, and a reflectance adjustment layer and a photocatalytic layer are preferably provided between the base material and the bumpy portion or the uneven layer, in that high hydrophilicity is exhibited and an anti-reflective effect is achieved.

The coating film or coating layer preferably contains SiO₂ as a main component in terms of enhancing the photocatalytic effect of the TiO₂, increasing hydrophilicity, and enhancing optical properties.

The bumpy portion or the uneven layer is preferably formed by etching, in that it allows control and easy production of the fine uneven structure and the porous structure.

The bumpy portion or the uneven layer preferably includes a particle containing layer having the shape of an uneven structure and an intermediate layer that adjusts the shape of the particles of the particle containing layer, and the intermediate layer and the particle containing layer are preferably formed on the base material in this order, in terms of being able to control the size and pitch of the gap through which the active chemical species of the photocatalyst passes.

The intermediate layer preferably has a dent formed by etching in that the size and period of the unevenness can be controlled and the function of the functional film can be optimized.

The total transmittance of the functional film is preferably 70% or more, in terms of excellent optical properties.

The production method of the functional film of the present invention includes a process of forming an unevenness unformed layer on the base material by the dry layer forming process. This allows easy production of the functional film having a fine uneven structure.

After the process of forming the unevenness unformed layer, the production method of the functional film of the present invention preferably includes a process of exposing the base material to an environment containing moisture to form the bumpy portion or the uneven layer. This makes it possible to easily form the bumpy portion or the uneven layer in the form of uniformly distributed particles and to obtain a functional film with good properties. A material (compound) having a solubility in water at 20° C. of 0.5 g/100 mL or more is preferably used at this time, in terms of efficient particle formation.

After the process of forming the bumpy portion or the uneven layer, the production method of the functional film of the present invention preferably includes a process of forming the coating layer or the coating film on the bumpy portion or the uneven layer by the dry film forming process. This allows easy production of the fine uneven structure and porous structure, and fixation of the bumpy portion or uneven layer by the coating layer or coating film so as not to peel off.

After the film forming process of the functional film, the production method of the functional film of the present invention preferably includes a process of storage in the high temperature and high humidity environment to reduce anionic components, in terms of improved hydrophilicity.

Furthermore, after the film forming process of the functional film, the production method of the functional film of the present invention preferably includes a process of exposure to an environment containing an etching gas so as to adjust the size of the gap through which the active chemical species generated by the photocatalyst reaction can pass.

Etching usually means scraping a sample surface by chemically and physically attacking the sample surface with a plasma-activated etching gas. However, because the colliding molecules also act as an abrasive in such etching, the surface becomes smooth and the pores at an atomic level are blocked. On the other hand, exposure to the environment containing etching gas as described above can expand the pores by the corrosive gas that has entered the pores, without blocking the gaps. This allows to obtain a more porous structure and to further increase the passing efficiency of the photocatalyst.

Hereinafter, the invention, its components, and the embodiments and modes of carrying out the present invention will be described. The term “to” as used in this application means that the values listed immediately before and after it are respectively included as the lower and upper limits.

### [Summary of the Functional Film of the Present Invention]

The functional film of an embodiment of the present invention is provided on a base material and has a fine uneven structure on its surface, and the fine uneven structure includes a coating film or a coating layer that is provided on a surface of the base material or constituent layers and covers at least a bumpy portion or an entire surface of the base material or the constituent layer. A mutual positional relationship and shape of a plurality of bumps and dents of the fine uneven structure have randomness with no regularity in terms of identity or periodicity to an extent such that no diffracted light occurs.

The functional film of another embodiment of the present invention is provided on a base material and has a fine uneven structure on its surface, and has at least one uneven layer and a coating layer provided on the uneven layer.

In the present invention, “bumps and dents” includes not only a layer with unevenness (for example, the uneven layer described above) but also particles that do not appear to be a layer.

In the present invention, “an extent such that no diffracted light occurs” means that there occurs no diffracted light due to interference of multiple beams of reflected light from bumps and dents or interference of beams of the incident light and reflected light.

When a fine uneven structure is formed by an etching process using lithography or by nanoimprinting using a mold, diffracted light occurs because the uneven structure has regularity. However, in the present invention, since the fine uneven structure is formed by the dry forming process as described later, an irregular (random) fine structure is formed, and thus no diffracted light occurs.

The presence or absence of the diffracted light can be checked, for example, by placing a sample of the functional film between the helium-neon laser and a screen, irradiating the screen with the laser through the sample, and then visually checking the laser on the screen.

In the present invention, “fine uneven structure” means a structure having multiple bumps and dents shapes that are fine enough to express the action as a functional film, and satisfies at least the following: the average height of the bumps is 1 μm or less, or in other words, the average depth of the dents is 1 μm or less, with respect to the bottom of the dent.

The fine uneven structure preferably has an arithmetic average roughness Ra of bumps in the range of 2 to 50 nm, a maximum height of bumps in the range of 10 to 500 nm, and an average diameter of the bumps in the range of 10 to 1000 nm in the vertical cross section, such that the abrasion resistance and functional film properties can be amplified.

### <Arithmetic Average Roughness Ra>

In the present invention, the arithmetic average roughness Ra of the bumps is preferably within the range of 10 to 40 nm, particularly preferably within the range of 15 to 30 nm.

The arithmetic average roughness Ra of the bumps is the average of roughness as 10 or more portions including bumps using an atomic force microscope (L-Trace, manufactured by Hitachi High-Tech Science Corporation) and satisfies the aforementioned conditions.

### <Maximum Height>

In the present invention, the maximum height of the bumps is preferably within the range of 50 to 200 nm, particularly preferably within the range of 70 to 150 nm.

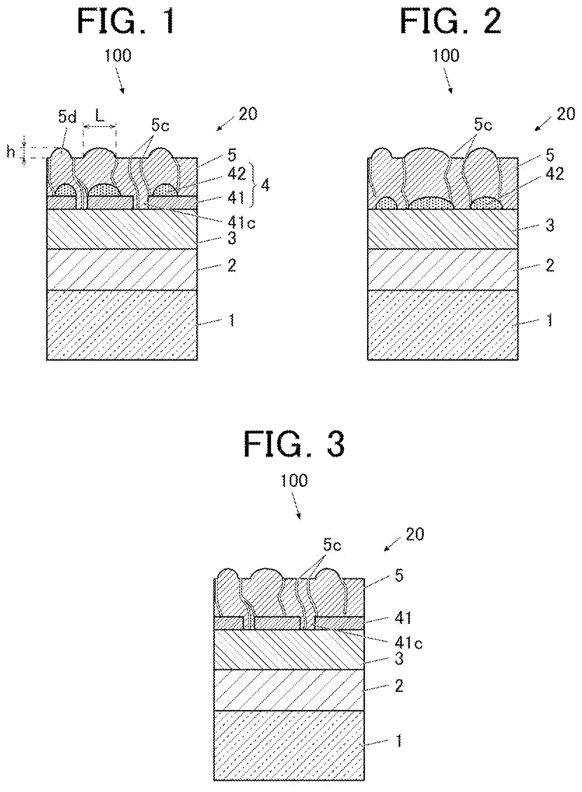

In the present invention, “the maximum height of the bumps” is the distance h from the lowest position to the outermost (uppermost) surface of the bump 5d in the vertical section (cross-section in the thickness direction) of the fine uneven structure, for example, as shown in FIG. 1.

The maximum height of the bumps is the maximum of heights of 10 or more bumps measured using an atomic force microscope (L-Trace, manufactured by Hitachi High-Tech Science Corporation) and satisfies the aforementioned conditions.

### <Average Diameter>

In the present invention, the average diameter of the bumps is preferably within the range of 30 to 500 nm, particularly preferably within the range of 50 to 200 nm.

In the present invention, “the average diameter of the bumps” is obtained when the fine uneven structure is viewed from the top, that is, when the entire fine uneven structure is photographed with an electron microscope from the top and observed. For example, it is the average diameter L of the bump 5d as shown in FIG. 1.

The average diameter of the bumps can be obtained using an electron microscope (S-4800 manufactured by Hitachi High-Tech Science Corporation). Specifically, the average of 10 or more measurements of the bumps satisfies the aforementioned conditions.

As described below, by using the production method of the functional film of the present invention, the arithmetic average roughness Ra, maximum height, and average diameter of the bumps can be controlled to be within the aforementioned ranges. Specifically, at least one uneven layer and a coating layer on the uneven layer are preferably formed by a dry process.

The functional film of the present invention preferably has a total transmittance of 70% or more in terms of excellent optical properties, and particularly preferably in the range of 80 to 99%. The greater the total transmittance, the higher the transparency, which is preferred.

The total transmittance of the functional film was measured using a turbidity (haze) meter NDH5000SP (manufactured by Nippon Denshoku Industries Co., Ltd.).

The total transmittance can be adjusted to 70% or more by appropriate selection of materials for each layer of the functional film.

In the following, specific examples of XPS analysis conditions applicable to the composition analysis of the functional films of the present invention are shown.

Analysis device: Quantera SXM manufactured by ULVAC-PHI, Inc.

X-ray source: monochromatized Al-Kα, 15 kV-25 W

Sputter ion: Ar (2 kV)

Depth profile: Measurements are repeated at predetermined thickness intervals, and a depth profile in the depth direction is obtained. Specifically, measurements are performed every 2.5 nm in the sputter thickness of SiO₂ equivalent to obtain data every 2.5 nm in the depth direction.

Quantification: Background is determined by Shirley method and quantification is made from the obtained peak area using the relative sensitivity coefficient method. Data are processed using analysis software MultiPak (manufactured by ULVAC-PHI, Inc.).

X-ray photoelectron spectroscopy (XPS) is a method of analyzing the constituent elements of a sample by irradiating the sample with X-rays and measuring the energy of the generated photoelectrons.

The elemental concentration distribution curve in the thickness direction of the functional film of the present invention (hereinafter referred to as “depth profile”) is obtained by sequential analysis of surface composition while exposing the inside of the functional film from the surface by combining measurement of the surface elemental composition of the sample and sputtering with a rare gas ion such as argon (Ar).

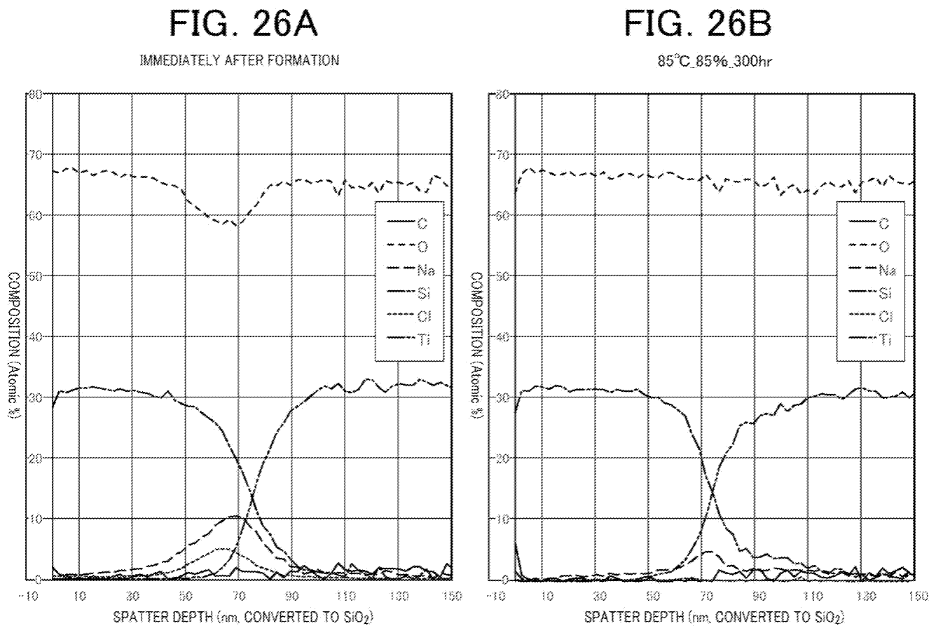

The distribution curve obtained by such XPS depth profile measurement can be prepared, for example, by setting the atomic concentration ratio of each element (unit: atomic %) on the vertical axis and the etching time (sputtering time) on the horizontal axis (see FIG. 26A and FIG. 26B, for example).

In the element distribution curve with etching time on the horizontal axis, etching time is approximately correlated with the distance from the surface of the functional film to the measurement position in the layer thickness direction of the functional film. Therefore, “the distance from the surface of the functional film in the thickness direction of the functional film” can be the distance from the surface of the functional film calculated from the relationship between etching rate and etching time, which was applied in the XPS depth profile measurement.

The rare gas ion sputtering method using argon (Ar) as the etching ion species can be employed in such an XPS depth profile measurement. The etching rate can be measured for SiO₂ thermally oxidized film whose thickness is known in advance, and the etching depth is often expressed as a SiO₂ thermally oxidized film equivalent.

By the composition analysis as described above, it is possible to observe, for example, the change in composition of the functional film immediately after film formation and after a long time (300 hours) of placement in a high temperature and high humidity environment (85° C./85% RH) (see, for example, FIG. 26A and FIG. 26B).

It is preferable to store the functional film in the high temperature and high humidity environment after film formation because the anionic component of the functional film (for example, FIG. 26B) after a long time in the high temperature and high humidity environment is less than that of the functional film immediately after film formation (for example, FIG. 26A).

FIG. 1 to FIG. 3 are cross-sectional schematic diagrams showing examples of the basic structure of the functional film of the present invention.

As shown in FIG. 1 to FIG. 3, the functional film 100 is formed, for example, on the base material 1 described below, and has a fine uneven structure 20 on the surface.

Specifically, the functional film 100 preferably has at least one uneven layer 4 and a coating layer 5 provided on the uneven layer 4.

The functional film 100 preferably has, between the base material 1 and the uneven layer 4, a reflectance adjustment layer 2 and photocatalytic layer 3 in this order from the base material 1 side.

In the above configuration, the uneven layer 4 is a layer having unevenness, but it may also be a bumpy portion including not only such a layer but also a non-layered particle-like portion.

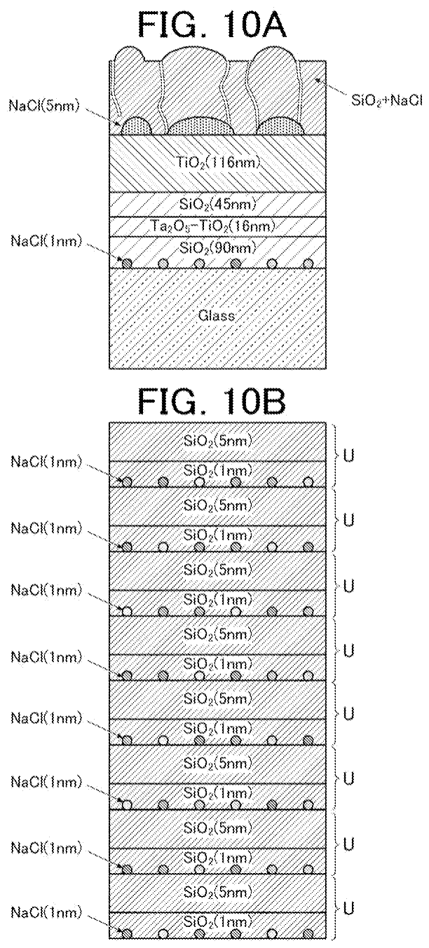

The above mentioned uneven layer 4 is preferably a layer formed by a dry process (dry-processed layer). The uneven layer 4 preferably includes a particle containing layer 42 that contains particles and an intermediate layer 41 that adjusts the shape of the particles in the particle containing layer 42. The uneven layer 4 preferably has an intermediate layer 41 on the photocatalytic layer 3, and the particle containing layer 42 on the intermediate layer 41. The particle containing layer 42 may be provided not only on the intermediate layer 41, but also, for example, between the base material 1 and reflectance adjustment layer 2 (see NaCl (1 nm in thickness) in FIG. 7 and NaCl (1 nm in thickness) in FIG. 10A). The particle containing layer 42 may be further provided between the coating layers 5 (see SiO₂ (1 nm in thickness) and SiO₂ (5 nm in thickness) in FIG. 10B) (see NaCl (1 nm in thickness) in FIG. 10B).

The functional film of the present invention preferably has at least one compound that constitutes the functional film having a solubility in water at 20° C. of 0.5 g/100 mL or more. A part of the functional film more preferably contains an inorganic salt, and in particular, an alkali metal salt or an alkaline earth metal salt. The compound having the solubility described above may be contained in any of the layers in the functional film, but is preferably contained in the particle containing layer that constitutes the functional film, as described below.

Next, preferred configuration examples of the functional film of the present invention are shown below, but they do notlimit the present invention. The coating layer in the configuration below may be the coating film described above. The particle containing layer below may be a layer formed by covering particles with a coating film or a coating layer.

(1) base material 1/reflectance adjustment layer 2/photocatalytic layer 3/intermediate layer 41/particle containing layer 42/coating layer 5 (see FIG. 1)
(2) base material 1/reflectance adjustment layer 2/photocatalytic layer 3/particle containing layer 42/coating layer 5 (see FIG. 2)
(3) base material 1/reflectance adjustment layer 2/photocatalytic layer 3/intermediate layer 41/coating layer 5 (see FIG. 3)

In the above configuration example (1), on the base material 1, the reflectance adjustment layer 2, photocatalytic layer 3, intermediate layer 41, particle containing layer 42, and coating layer 5 are stacked in this order. The configuration example (2) is the configuration example (1) without the intermediate layer 41. The configuration example (3) is the configuration example (1) without the particle containing layer 42.

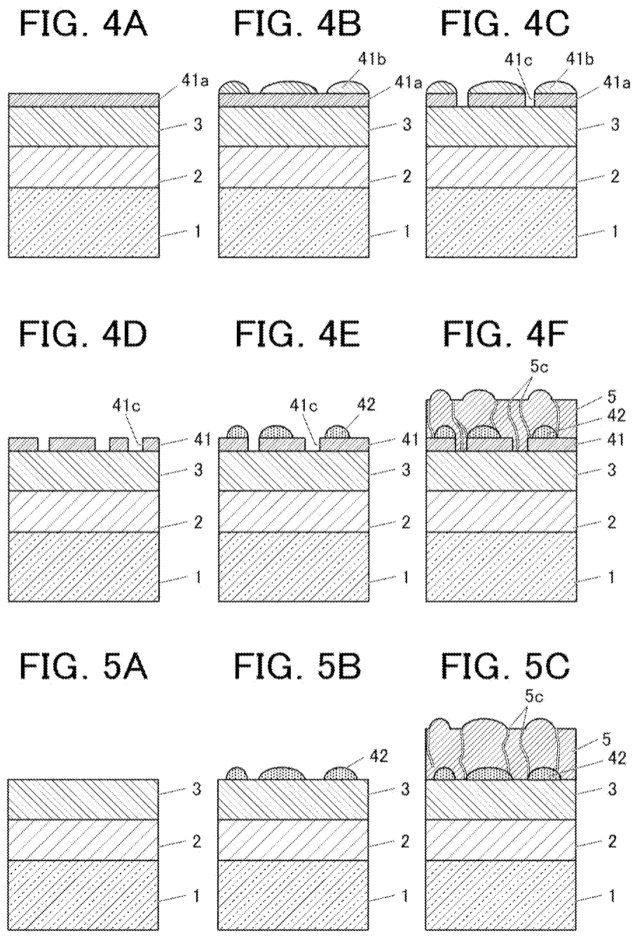

In FIG. 1 to FIG. 3, the uneven shape of the coating layer 5 and the size and number of particles in the particle containing layer 42 are all described schematically in the same way. However, the shape of the unevenness and the size and number of the particles may actually be different from figure to figure. The same is true for FIG. 4A and subsequent figures.

The following is an explanation of each layer configuration in configuration example (1).

### <Coating Film or Coating Layer>

The functional film of an embodiment of the present invention is characterized by having the fine uneven structure that includes one of a coating film and a coating layer that is provided on a surface of the base material or a constituent layer and covers at least a bumpy portion or an entire surface of the base material or the constituent layer. That is, the fine uneven structure may have a bumpy portion and a coating film or coating layer, or only a bumpy portion without a coating film or coating layer. However, the former is preferred.

The coating film or coating layer of the present invention may have an inorganic or organic material as components of the film with a property such as hydrophilic, anti-fog, hydrophobic, lipophilic, and water repellency depending on the desired function. Therefore, the coating film or coating layer may also perform the main function of the functional film of the present invention.

For example, when a hydrophilic material is used, the finer the uneven structure, that is, the more the surface roughness becomes, the more specific surface area (the area ratio of the rough surface to the plane before the uneven structure is provided), the smaller contact angle, and the more hydrophilic property the hydrophilic surface has. On the other hand, when a hydrophobic material is used, the finer the uneven structure, the larger contact angle and the more hydrophobicity the hydrophobic surface has.

In the present invention, a “film” refers to an object whose thickness is very small with respect to its surface area and is very thin. On the other hand, a “layer” refers to stacked objects or each of the stacked objects.

The above mentioned films and layers are not limited to continuous films or layers having an uncertain or certain length or width, but may also be intermittent or dot-shaped isolated films or layers.

Therefore, the above mentioned “coating film” can also be formed as a “coating layer”.

Although the coating layer of the present invention is a layer that has a function of protecting the constituent materials of the underlying layer, it can also have various additional functions. Specifically, for example, the coating layer may function as a hydrophilic layer, a water-repellent layer, an anti-reflective layer, or an anti-fog layer.

### (Hydrophilic Layer)

When the coating layer of the present invention is a hydrophilic layer, the hydrophilic layer preferably includes SiO₂ as the main component.

In the present invention, the phrase “the hydrophilic layer preferably includes SiO₂ as the main component” means that the ratio of SiO₂ among all the components constituting the hydrophilic layer is 80% by mass or more, preferably 90% by mass or more and 99.9% by mass or less, particularly preferably 97% by mass or more and 99.9% by mass or less.

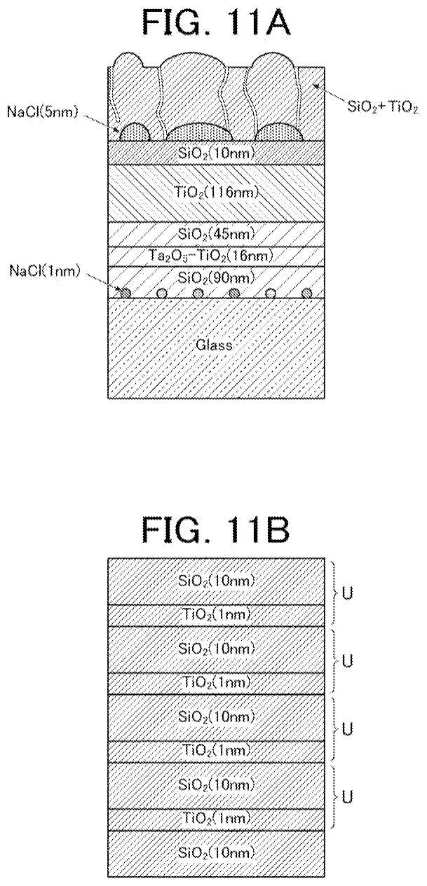

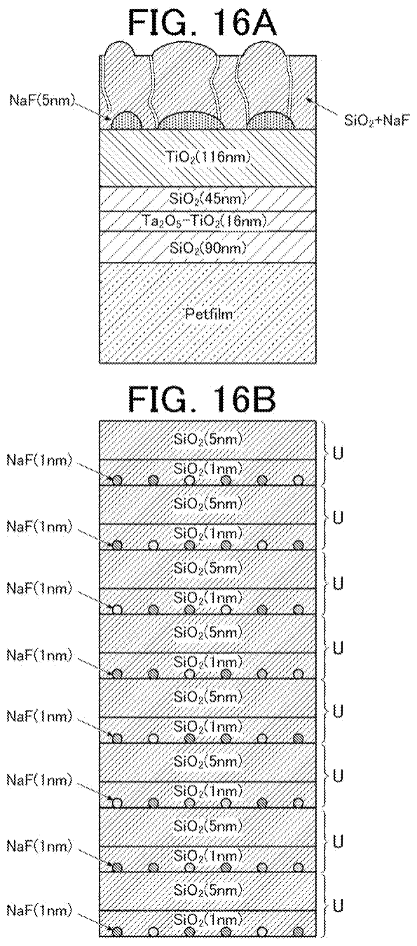

The hydrophilic layer preferably includes a plurality of SiO₂ layers stacked together. The hydrophilic layer preferably includes SiO₂ as the main component, and the particle containing layer mentioned above may be provided between the hydrophilic layers. Specifically, a layer containing NaCl particles, an alkali metal salt as an inorganic salt (NaCl layer), may be provided between the plurality of stacked SiO₂ layers (for example, see FIG. 10B). A layer containing NaF particles (NaF layer) may be provided between the stacked SiO₂ layers (for example, see FIG. 16B). Furthermore, the hydrophilic layer may also have a TiO₂ layer between the SiO₂ layers (for example, see FIG. 11B).

By providing particle containing layers between the hydrophilic layers, the functional film can have a finer uneven structure.

The hydrophilic layer composed of the SiO₂ layer and the TiO₂ layer alternately stacked can form a more porous structure due to the stacking of layers of different components compared to the hydrophilic layer composed only of the SiO₂ layer.

The entire thickness of the hydrophilic layer is preferably in the range of 5 to 5000 nm, and particularly preferably in the range of 50 to 500 nm.

When the SiO₂ layers are stacked as described above, the thickness of each SiO₂ layer is preferably in the range of 5 to 50 nm, and SiO₂ layers of different thicknesses are preferably stacked alternately. In this case, units each consisting of a thinner lower SiO₂ layer and a thicker upper SiO₂ layer are preferably stacked (for example, see FIG. 10B).

The thickness of the NaCl layer or the NaF layer between the SiO₂ layers is preferably in the range of 0.1 to 10 nm. Furthermore, the thickness of the TiO₂ layer between the SiO₂ layers is preferably in the range of 0.1 to 10 nm.

The hydrophilic layer is preferably formed by a dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred.

In particular, the formation of a thin SiO₂ layer by IAD followed by the formation of a thick SiO₂ layer by vacuum vapor deposition without IAD is preferable because the adhesion with the underlying layer can be strong and a porous film can be formed. The rotation speed of the base material is preferably slow. It is preferable to tilt the base material with respect to the angle of incidence of the atoms to form layers using the shading effect. This allows for the formation of a porous film.

The IAD method described above is a method to make a dense film by applying the high kinetic energy of ions, and the formed film has high adhesion strength. For example, in the ion beam method, ionized plasma particles emitted from the ion source hit the adhered material and form a film on the surface of the base material.

### (Water-Repellent Layer)

When the coating layer of the present invention is a water repellent layer, the water repellent layer is preferably configured from a water repellent material such as fluorine-based and silicone-based water-repellent materials.

The water repellent material is specifically Fluoro Surf (Registered Trademark) (manufactured by Fluoro Technology Co., LTD.), OPTOOL (manufactured by Daikin Industries, Ltd.), SURFCLEAR 100 (manufactured by Canon Optron, Inc.), or the like, and is particularly preferably SURFCLEAR 100.

The water repellent layer is preferably formed by a dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred.

The thickness of the water repellent layer is preferably in the range of 5 to 100 nm.

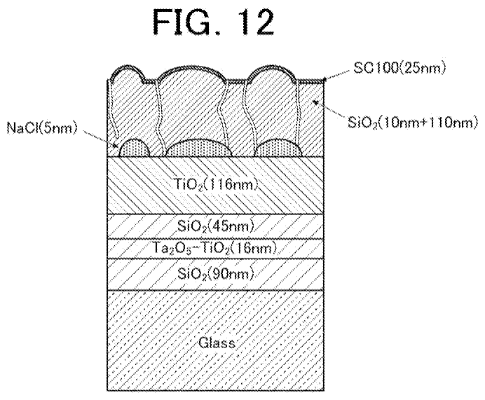

The water-repellent layer may be formed on the hydrophilic layer (see, for example, SC100 (25 nm in thickness) in FIG. 12.

It is preferable to form a slip film before forming the water-repellent layer because it is effective in preventing fogging, improves adhesion, provides both rub resistance and super water repellency, and can be applied to optical devices.

The preferably selected slip film has a contact angle of 40 to 120 degrees when a single 100 nm film is formed on a Super White Glass substrate manufactured by Schott AG and left at room temperature for 3 days. A particularly preferred slip film has a contact angle that differs from the contact angle of the main component of the fine structure by 20 degrees or more.

The main component(s) of the slip film is, for example, Ta₂O₅—TiO₂ (manufactured by Canon Optron, Inc. product name: OA-600), Ta₂O₅, TiO₂, SiC, Al₂O₃, and HfO₂, and the like.

The slip film is formed, for example, by IAD, sputtering, and chemical vapor deposition (CVD), in addition to the usual vacuum vapor deposition. The thickness of the slip film is preferably in the range of 0.1 to 20 nm.

### (Anti-Fog Layer)

When the coating layer of the present invention is an anti-fog layer, the anti-fog layer can be formed, for example, by providing pluralities of stacked structures each having a particle containing layer between the hydrophilic layers.

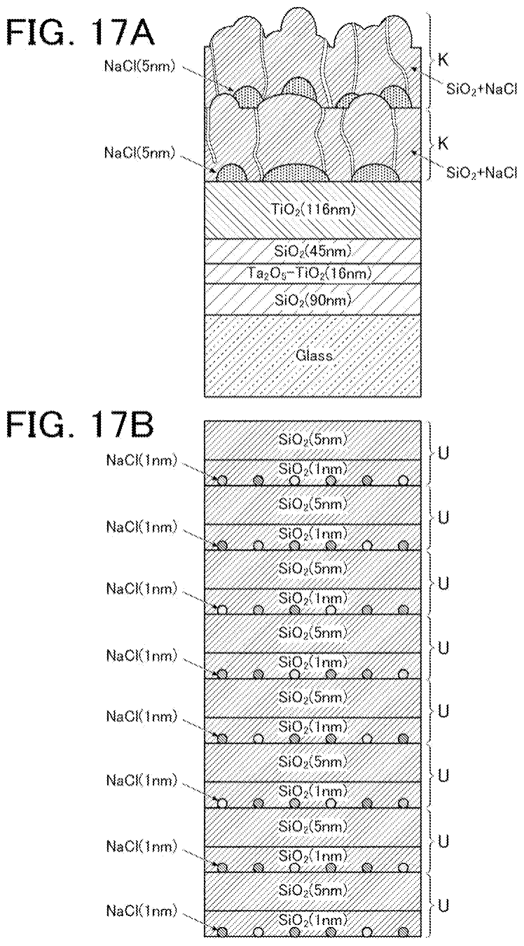

The configuration of the anti-fog layer is shown, for example, in FIG. 17A and FIG. 17B. FIG. 17B shows the details of the layer labeled “SiO₂+NaCl” in FIG. 17A. The anti-fog layer shown in FIG. 17A and FIG. 17B has a photocatalytic layer (TiO₂ layer) and two stacked structures K on the photocatalytic layer (TiO₂ layer). Each of the stacked structures K includes a NaCl layer (5 nm in thickness) and eight units U on the NaCl layer (5 nm in thickness). Each of the units U includes a NaCl layer (1 nm in thickness), a SiO₂ layer (1 nm in thickness), and a SiO₂ layer (5 nm in thickness) stacked in this order.

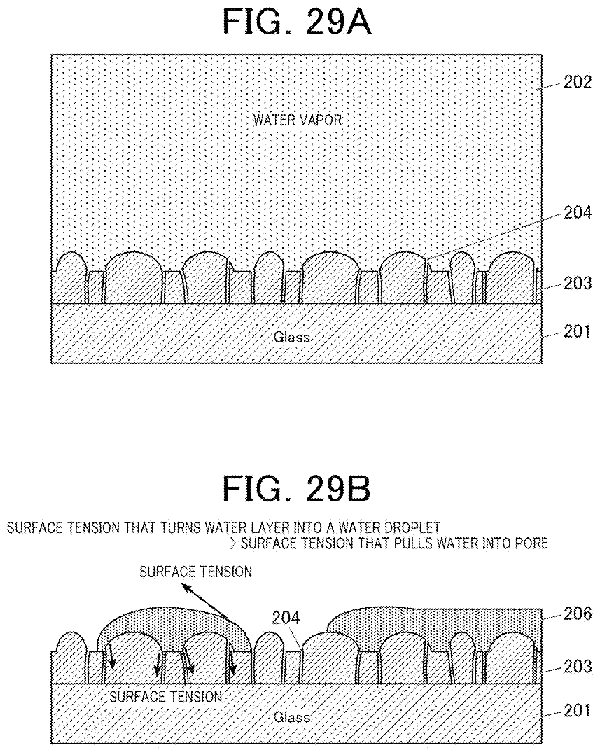

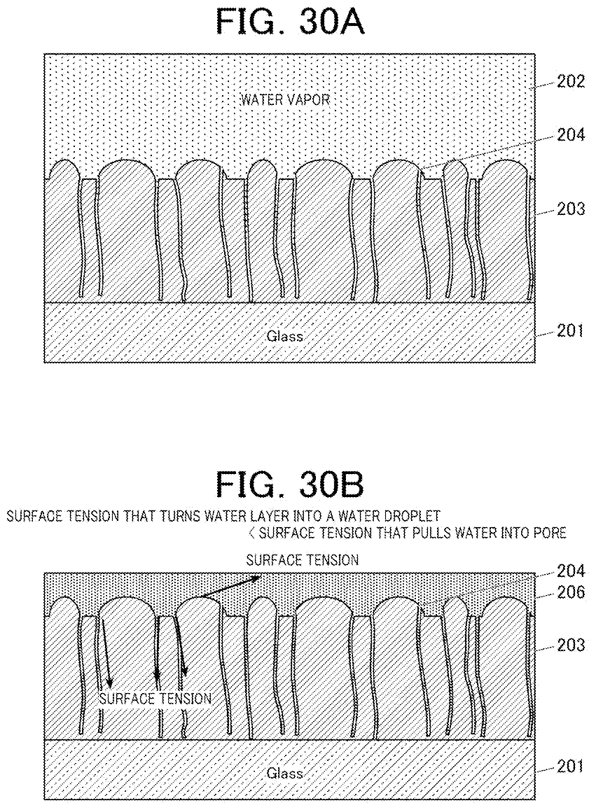

The principle of the anti-fog effect of the anti-fog layer is explained here based on FIG. 28A to FIG. 30B. FIG. 28A, FIG. 29A, and FIG. 30A are schematic diagrams of each functional film each placed in the high temperature and high humidity environment. FIG. 28B, FIG. 29B, and FIG. 30B are schematic diagrams showing the relationship between surface tension that forms a water droplet and surface tension that pulls water along the base material or into pores. In these drawings, the reference sign 201 represents the base material, reference sign 202 represents water vapor, reference sign 203 represents the functional film, reference sign 204 represents the pore, reference sign 205 represents a water droplet, and reference sign 206 represents a water layer.

When a coating layer is formed on the uneven layer by a dry process, atomic-level pores are formed between the uneven layer and the coating layer due to the shading effect. When the surface of the functional film is exposed to water vapor, the water vapor first enters the pores. Next, when the surface tension in the pores exceeds the surface tension that turns the water layer into a water droplet(s), the anti-fog effect is achieved.

When there are no pores 204 as shown in FIG. 28A and FIG. 28B, there is insufficient surface tension between the surface of the glass base material 201 and the water layer to keep the water in a layered state, and the water layer quickly turns into small water droplets 205 of 10 to 100 μm, resulting in fogging.

On the other hand, in FIG. 29A and FIG. 29B, the water vapor 202 enters the pores 204 of the somewhat thin functional film 203. Because the surface tension in these pores 204 is somewhat insufficient to maintain the water layer, the water layer 206 is partly maintained and partly turned into water droplets 205, resulting in a mixed state of cloudiness.

When deep pores 204 are formed in a sufficiently thick functional film as shown in FIG. 30A and FIG. 30B, the surface tension in the deep pores 204 is greater than the surface tension that turns the water layer 206 into a water droplet(s). This sufficient anchoring effect prevents the water layer 206 to turn into a water droplet, and the anti-fog effect is achieved.

From the above principles, the following can be understood. The deeper the pores, the better. Numerous atomic-level pores are preferably evenly distributed because, in this case, there is no portion with low anti-fog effect. The pores are preferably large enough not to be clogged under the high temperature and high humidity environment. When the active chemical species in the photocatalyst are not deactivated at high temperature and high humidity, the pore size can be considered suitable. Deactivation means clogging, which of course means that there is no place for water vapor to enter. In other words, the surface tension is not sufficient to maintain the water in a layered state, and the anti-fog effect is not achieved. Since this anchoring effect of course improves hydrophilic properties, the above concept can be applied to hydrophilic films as well.

The anti-fog layer is preferably formed by a dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred.

The thickness of the anti-fog layer is preferably in the range of 10 to 5000 nm.

An anti-fog functional film whose coating layer is an anti-fog layer may not have a photocatalytic layer described below.

### <Uneven Layer>

The uneven layer according to the present invention is a layer that serves as a prototype or underlying layer of the outermost surface of the functional film having the fine uneven structure, and has a bump shape such as a particle shape or an island shape.

The functional film of a preferred embodiment of the present invention has a coating film or coating layer made of a material having the desired function on the uneven layer.

The coating film or coating layer may have a coating film or coating layer covering at least a bumpy portion or the entire surface of the uneven layer. Furthermore, the coating film or coating layer may have a plurality of stacked coating films or coating layers according to the application.

The uneven layer according to the present invention may not necessarily have a coating film or a coating layer, depending on the material constituting the uneven layer.

The uneven layer according to the present invention may have various configurations, but is preferably a layer including a particle containing layer having the shape of the uneven structure described below. Furthermore, the uneven layer preferably includes an intermediate layer described below.

### <Particle Containing Layer in a Shape Having an Uneven Structure>

A “particle containing layer in the shape having an uneven structure” according to the present invention is one embodiment of the above uneven layer and refers to a layer that has an uneven shape based on the shape of particles.

For example, during the production process of the functional film, particles (for example, sodium chloride crystal particles) are first formed or arranged in a particulate form on a surface of an under layer (for example, the base material or the reflectance adjustment layer) that finally serves as the underlying layer of the particle containing layer and then covered with a coating film or coating layer. A layer recognized as a layer in the shape having the uneven structure including particles is thereby formed.

There are various methods of forming or arranging particles in the particle shape. In one of the preferred methods, a film or layer (“unevenness unformed layer” described below) as a “precursor of a particle containing layer in the shape having an uneven structure” that consists of particle constituents or particle aggregates and does not yet have a predetermined fine uneven structure is first formed by a dry process and then exposed to an atmospheric environment containing moisture such that the particle aggregates in the unevenness unformed layer become separated and isolated particles, so as to become a layer including the uneven shape formed by the isolated particles (dots), that is, a layer having the fine uneven structure.

The compound contained in the particle containing layer having the uneven structure preferably has a solubility of 0.5 g/100 mL or more in water at 20° C. In this case, the precursor layer without the uneven structure (that is, the unevenness unformed layer) of the particle containing layer in the shape having the uneven structure formed by a dry process contains moisture when exposed to air and water vapor, so that uniformly distributed particles are easily formed.

Examples of compounds having solubility of 0.5 g/100 mL or more include LiCl (solubility: 76.9 g/100 mL (20° C.)), NaCl (solubility: 35.9 g/100 mL (20° C.)) MgCl₂.6H₂O (solubility: 54.3 g/100 mL (20° C.)), KCl (solubility: 34.0 g/100 mL (20° C.)), CaCl₂ (solubility: 74.5 g/100 mL (20° C.)), Na₂CO₃ (solubility: 22 g/100 mL (20° C.)), NaF (solubility: 4.06 g/100 mL (20° C.)), and the like.

The compound is preferably an inorganic salt, and at least a part of the inorganic salt is preferably an alkali metal salt in terms of improved resistance to high temperature and high humidity of the hydrophilic property.

Examples of preferred inorganic salts of alkali metals whose solubility is within the above range include NaCl, NaF, and MgCl₂.6H₂O, and the like.

The average particle diameter of the particles included in the particle containing layer is preferably in the range of 10 to 1000 nm. The average particle diameter can be measured using an electron microscope (5-4800, manufactured by Hitachi High-Tech Science Corporation).

The particle containing layer is preferably formed by a dry process, in that uniformly distributed fine uneven structures and porous structures can be easily produced.

Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred. In particular, resistance heating vacuum vapor deposition is preferred.

The thickness of the particle containing layer formed as described above is preferably in the range of 0.1 to 100 nm.

The functional film preferably includes at least one particle containing layer. The particle containing layer is preferably provided at least adjacent to a lower surface of the coating layer. As described above, the coating layer may partly include the particle containing layer (see, for example, NaCl (1 nm in thickness) in FIG. 10B). The particle containing layer may be provided between the base material and the reflectance adjustment layer (see, for example, NaCl (1 nm in thickness) in FIG. 7).

### <Intermediate Layer>

The intermediate layer is a layer provided on the base material to adjust the shape of the particles contained in the particle containing layer. When the reflectance adjustment layer or photocatalytic layer is provided on the base material, the intermediate layer is preferably provided on the reflectance adjustment layer and photocatalytic layer.

The intermediate layer preferably includes an inorganic material as the main component. Examples of the inorganic material are not limited to, but include Ta₂O₅—TiO₂ (OA600 manufactured by Canon Optron, Inc.), HfO₂, Y₂O₃, LaF, CeF, SiO₂, and the like. SiO₂ is particularly preferred in terms of hydrophilicity.

The intermediate layer is preferably formed by a dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred. IAD is particularly preferred.

The intermediate layer formed by the dry process is preferably subjected to etching to have dents so that the underlying photocatalytic layer can effectively exhibit the photocatalytic effect. In other words, as described later, the pores 5c of the coating layer 5 are preferably arranged in the dents 41c. This allows the pores 5c to be connected to the photocatalytic layer 3, and the active chemical species generated in the photocatalytic layer 3 can pass through the pores 5c (see FIG. 1).

The average diameter of the dents is preferably in the range of 10 to 1000 nm. The average diameter of the dents can be obtained using the electron microscope (5-4800 manufactured by Hitachi High-Tech Science Corporation).

The thickness of the intermediate layer is preferably in the range of 0.1 to 100 nm.

### <Photocatalytic Layer>

The photocatalytic layer according to the present invention preferably includes TiO₂ as a metal oxide having a photocatalyst function as the main component, in order to achieve a high refractive index and a reduction of optical reflectance of the functional film.

In the present invention, the phrase “the photocatalytic layer preferably includes TiO₂ as the main component” means that the ratio of TiO₂ among all the components constituting the photocatalytic layer is 80% by mass or more, preferably 90% by mass or more and 99.9% by mass or less, particularly preferably 97% by mass or more and 99.9% by mass or less.

The “photocatalyst function” of the present invention refers to the organic matter decomposition effect by the photocatalyst. When TiO₂ having a photocatalytic property is irradiated with ultraviolet light, the active chemical species such as activated oxygen or hydroxyl radicals (.OH radical) are generated after electrons are emitted, and decomposes organic matter by its strong oxidizing power. The photocatalytic layer containing TiO₂ added to the functional film of the present invention can prevent organic matter and the like adhering to an optical member from contaminating the optical system as stains.

The photocatalytic layer is preferably formed by a dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred. IAD is particularly preferred.

Between the adjacent bumps and dents of the fine uneven structure, there is preferably a gap through which the active chemical species generated in the photocatalyst can pass. Specifically, as shown in FIG. 1, pores 5c are preferably formed in the coating layer 5. The pores 5c are formed due to the porous structure of the coating layer 5 formed by a dry process on the uneven layer 4, which is a particle containing layer 42 or intermediate layer 41. Due to the shading effect that occurs when a film is formed by vapor-deposited particles from a certain direction on the uneven layer 4, many pores remain in the vicinity of the unevenness. Therefore, rotation during film formation is preferably slow or intermittently stopped. It is also preferable to tilt the base material with respect to the angle of incidence of the vapor-deposited atoms to form films using the shading effect. This allows for the formation of a porous film.

The pores 5c pass between the particles of the particle containing layer 42 and through the dents 41c formed as a result of etching of the intermediate layer 41, and are connected to the photocatalytic layer 3. The average diameter of the pores 5c is preferably in the range of 0.1 to 10 nm.

Whether or not such pores (gaps) are formed can be determined by checking whether or not the surface of the functional film has a photocatalytic effect. It can be determined, for example, by irradiating a sample that is colored with a methylene blue ink pen with ultraviolet light at an integrated light intensity of 20 J at 20° C. and 80% RH and by evaluating the color change of the pen step by step. Specific examples of a photocatalyst performance test on self-cleaning using ultraviolet light irradiation include the methylene blue decomposition method (ISO 10678 (2010)) and the Resazurin ink decomposition method (ISO 21066 (2018)).

Even when the functional film does not have a photocatalytic layer (for example, anti-fog functional film), whether or not the pores are formed is determined by forming a photocatalytic layer on the base material, forming an anti-fog layer and the like on the photocatalytic layer, coloring the film with a methylene blue ink pen, irradiating it with ultraviolet light, and then evaluating the color change of the pen step by step.

### <Reflectance Adjustment Layer>

The reflectance adjustment layer of the present invention preferably includes at least one low refractive index layer and at least one high refractive index layer.

The reflectance adjustment layer, for example, consists of a first low refractive index layer, a high refractive index layer, and a second low refractive index layer, in order from the base material. The following is an example of the material and thickness of each layer, which does not limit the present invention.

1) First low refractive index layer: constituent material=SiO₂, layer thickness=90 mn
2) High refractive index layer: constituent material=Ta₂O₅—TiO₂, layer thickness=16 nm
3) Second low refractive index layer: constituent material=SiO₂, layer thickness=45 mn

The above configuration is merely an example, and the order of the low refractive index layer and high refractive index layer may be changed, or even more low refractive index layers and high refractive index layers may be stacked.

### <First Low Refractive Index Layer and Second Low Refractive Index Layer>

The first and second low refractive index layers of the present invention are configured from materials having a refractive index of less than 1.7, and in the present invention, these layers preferably include SiO₂ as the main component. However, the first and second low refractive index layers according to the present invention also preferably contain other metal oxides. A mixture of SiO₂ and some Al₂O₃ or MgF₂ is also preferred from the viewpoint of optical reflectance.

### <High Refractive Index Layer>

In the present invention, the high refractive index layer is configured from a material having a refractive index of 1.7 or more. The material of the high refractive index layer is, for example, a mixture of an oxide of Ta and an oxide of Ti, an oxide of Ti, an oxide of Ta, or a mixture of an oxide of La and an oxide of Ti, and the like. The metal oxide used in the high refractive index layer preferably has a refractive index of 1.9 or more. In the present invention, the metal oxide used in the high refractive index layer is preferably Ta₂O₅ or TiO₂, and more preferably Ta₂O₅.

In the present invention, the thickness of the reflectance adjustment layer including a high refractive index layer(s) and a low refractive index layer(s) is not particularly limited, but from the viewpoint of anti-reflective performance, preferably 500 nm or less, and more preferably in the range of 50 to 500 nm. When the thickness is 50 nm or more, the optical properties of anti-reflection can be achieved. When the thickness is 500 nm or less, the error sensitivity is reduced, and the percentage of products with excellent spectral characteristics of the lens can be increased.

The thickness of the first low refractive index layer in the above configuration example is preferably in the range of 5 to 150 nm, the thickness of the second low refractive index layer is preferably in the range of 5 to 100 nm, and the thickness of the high refractive index layer is preferably in the range of 1 to 70 nm.

The method of forming the reflectance adjustment layer including a low refractive index layer(s) and a high refractive index layer(s) is not particularly limited, but preferably a dry process is used.

Examples of the dry process applicable to the present invention based on vapor deposition include vacuum vapor deposition, ion beam vapor deposition, ion plating, ion-assisted vapor deposition (IAD), and the like. Examples of the dry process applicable to the present invention based on sputtering include sputtering, ion beam sputtering, magnetron sputtering, and the like. Among these, vacuum deposition, IAD, or sputtering is preferred. IAD is particularly preferred.

### <Base Material>

The base material from which the functional film is formed is not restricted, and preferably consists of an inorganic material, an organic material, or a combination thereof.

Examples of the inorganic material include glass, fused quartz glass, synthetic quartz glass, glass lens, silicon or chalcogenide.

Examples of the organic material include polyethylene terephthalate (PET), acrylic resins, vinyl chloride resins, cyclo-olefin polymers (COP), polymethyl methacrylate resins (PMMA), polycarbonate resins (PC), polypropylene (PP), and polyethylene (PE). Examples of UV curable resins are radical polymerization type acrylate resin, urethane acrylate, polyester acrylate, polybutadiene acrylate, epoxy acrylate, silicone acrylate, amino resin acrylate, and en-thiol resins, and cationic polymerization type vinylether resins, alicyclic epoxy resins, glycidyl ether epoxy resins, urethane vinylethers, and polyester vinylethers. Examples of thermosetting resins include epoxy resins, phenolic resins, unsaturated polyester resins, urea resins, melamine resins, silicone resins, polyurethane, and the like. The base material may be an inorganic material such as glass with a film made of an organic material on the inorganic material.

In the present invention, when the functional film of the present invention is used for optical devices as described below, glass is preferably used as the base material from the viewpoint of transparency. When the functional film of the present invention is used for an inkjet head, silicon is preferably used as the base material. When the functional film is used for a mold, SiC, ultra-hard alloys, or the like is preferably used as the base material.

### [Production Method of Functional Film]

The production method of the functional film of the present invention includes Step (I) of forming an unevenness unformed layer on the base material by a dry process.

The method preferably includes, after Step (I), Step (Aging Step) (II) of exposing the unevenness unformed layer to the environment containing moisture to form the bumpy portion or the uneven layer. As a result, the bumpy portion or the uneven layer can be formed in a particulate form, which is preferred in that the properties of the resulting functional film are good.

The method further includes, after Aging Step (II), Step (III) of forming the coating layer or coating film on the bumpy portion or uneven layer by a dry process. This makes it possible to easily produce the fine uneven structure and a porous structure, and also to immobilize the bumpy portion or the uneven layer with the coating film or coating layer so that the bumpy portion or the uneven layer does not peel off.

The method preferably includes Step (IV) of storing the formed functional film in the high temperature and high humidity environment to reduce the anionic components contained in the film, in that it improves the hydrophilic property of the functional film.

The production method further preferably includes Step (V) of exposing the formed functional film to the environment containing the etching gas to adjust the size of gaps (pores) through which the active chemical species generated by the photocatalyst reaction can pass. This allows the pores to be enlarged by the corrosive gas that has entered the pores, resulting in a porous structure and further increasing passage efficiency of the photocatalyst.

### <Step (I) of Forming Unevenness Unformed Layer>

In the present invention, the “unevenness unformed layer” is a layer that is a precursor before the bumpy portion or uneven layer is formed, specifically, a layer formed by the dry process with the material of the bumpy portion or uneven layer and before being exposed to the environment containing moisture. Therefore, the unevenness unformed layer is not yet in the granular form that is formed by exposure to the environment containing moisture.

In Step (I), the unevenness unformed layer is formed on the substrate. The reflectance adjustment layer and photocatalytic layer may be provided on the base material, and the unevenness unformed layer may be formed on the photocatalytic layer. Alternatively, the reflectance adjustment layer or photocatalytic layer may not be provided on the base material, and the unevenness unformed layer may be formed directly on the base material. When the unevenness unformed layer is formed directly on the base material, the functional film functions as an anti-reflective film.

<Step (II) of Forming Bumpy portion or Uneven Layer>

In Step (II), the unevenness unformed layer formed in Step (I) is exposed to the environment containing moisture to form a bumpy portion or uneven layer.

Exposing the layer to the environment containing moisture means, for example, taking the layer out of the dry deposition equipment and leaving it outside.

The time for exposing the layer to the environment containing moisture (aging time) is preferably in the range of 0.5 to 300 hours.

In the following explanations of Step (I) and Step (II) of the production method of the functional film, the bumpy portion or uneven layer is specifically (i) an intermediate layer and particle containing layer (for example, see FIG. 1). However, when the bumpy portion or uneven layer is (ii) only the particle containing layer (see FIG. 2) or (iii) only the intermediate layer (see FIG. 3), the functional film can be produced in basically the same way.

FIG. 4A to FIG. 4F are process diagrams showing an example of the production method of the functional film.

### (1) Formation of Intermediate Layer

### (1.1) Formation of Inorganic Layer

As shown in FIG. 4a, the reflectance adjustment layer 2 and photocatalytic layer 3 are formed on the base material 1 by the method described above. On the photocatalytic layer 3, an inorganic layer 41a containing an inorganic material as the main component is formed by a dry process.

As for the formation of the layer by the dry process, the IAD method and the like are preferably used as described above.

The preferred thickness of the inorganic layer depends on the type of the inorganic material. The thickness of the inorganic layer of SiO₂ is preferably in the range of 1 to 400 nm, the thickness of the inorganic layer of SiC is preferably in the range of 1 to 1000 nm, the thickness of the inorganic layer of SiOC is preferably in the range of 1 to 500 nm, and the thickness of the inorganic layer of SiCN is preferably in the range of 1 to 500 nm.

### (1.2) Formation of Mask

Next, as shown in FIG. 4B, a mask 41b is formed on the inorganic layer 41a. The mask 41b is, for example, a metal mask consisting of a metal part and an exposure part.

The thickness of the metal mask is preferably in the range of 5 to 100 nm.

The metal mask depends on the formation conditions. For example, a metal mask with a thickness of 2 nm and formed using the vapor deposition at a substrate temperature of 370° C. and a rate of 3 Å is in particulate form. For example, a metal mask with a thickness of 12 to 15 nm formed using the vapor deposition at a substrate temperature of 170° C. and a rate of 3 Å is likely to be reticulate. Furthermore, for example, a metal mask with a thickness of 10 nm formed using the sputtering method at a substrate temperature of 30° C. and a rate of 3 Å is likely to be porous.

Thus, the uneven structure of the intermediate layer formed is controlled by the formation conditions of the metal mask, the substrate temperature, the formation rate, and the thickness to be formed.

In the present invention, the metal mask is formed, for example, of silver (Ag) or aluminum (Al), and is especially preferably formed of silver. The temperature at which the metal mask is formed is preferably in the range of 20 to 400° C. The uneven structure of the intermediate layer also depends on the temperature at which the metal mask is formed.

### (1.3) Etching

Next, as shown in FIG. 4C, using an etching device (not shown), etching is performed from the surface side through the mask 41B from the inorganic layer 41a to the upper surface of the photocatalytic layer 3. Specifically, the etching time is controlled so that the etching depth is in the range of 1 to 400 nm.

The frequency of the RF power supply for etching is preferably as low as possible, which reduces the cost of mass production equipment and is advantageous for large scale production. The frequency of the RF power supply during etching is preferably 1 MHz or less and more preferably 400 kHz, but is not necessarily so, depending on the performance of the device. In terms of increasing the etch selectivity of the metal mask, the power during etching is preferably 1 W/cm² or less, and even more preferably 0.1 W/cm² or less. The device preferably has a cooling device or heat dissipation mechanism to increase the etch selectivity of mask. If there is no mechanism for cooling, it is desirable to have a standby time to stop the power for cooling, to completely stop the power and open to the atmosphere for heat dissipation, or to use a pulse power supply to turn the power on and off intermittently.

The etching time is preferably in the range of 30 to 3000 seconds.

The etching is reactive dry etching using an etching device or is performed using an IAD vapor deposition device with an etching gas introduced. Examples of the etching gas include CHF₃, CF₄, COF₂, and SF₆. With this, etching is performed in a predetermined size from the inorganic layer 41a to the upper surface of the photocatalytic layer 3, and a plurality of dents 41c is formed. That is, the constituent layers corresponding to the exposed portions of the metal mask 41b are etched.

### (1.4) Removal of Mask

Next, as shown in FIG. 4D, the mask 41b formed on the surface is removed. Specifically, the metal mask is removed by wet etching using agents such as acetic acid, iodine, potassium iodide, and the like. The metal mask may be removed by dry etching using, for example, Ar or O₂ as an etching gas.

When the mask 41b is removed, the intermediate layer 41 is formed.

After that, an intermediate layer may be formed by forming the inorganic layer again, forming a second mask, performing a second etching, and performing a second peeling of the mask. This allows formation of an intermediate layer with finer pores.

Although dents are formed by etching in the intermediate layer described above, the dents may not be formed.

### (2) Formation of Particle Containing Layer

Next, the particle containing layer is formed on the intermediate layer.

(2.1) Formation of Layer with Material (Compound) Having Solubility of 0.5 g/100 mL or More in Water.

As shown in FIG. 4E, the unevenness unformed layer, which is the precursor before the particle containing layer (uneven layer) is formed, is formed on the intermediate layer 41 by the dry process with the above material.

The method of forming the layer by the dry process is preferably resistance heating vacuum vapor deposition, as described above.

The solubility of the material in water at 20° C. is preferably 0.5 g/100 mL or more in that uniformly distributed particles can be easily formed by formation of a layer containing the material by the dry process followed by exposure to an atmosphere and water vapor to apply moisture. The material is preferably an inorganic salt, and at least a part of the inorganic salt is particularly preferably an alkali metal salt in terms of improved resistance to high temperature and high humidity of the hydrophilic property.

### (2.2) Aging Step

After forming the layer with the above material whose solubility in water is 0.5 g/100 mL or more, a step of exposing the layer to the environment containing water (aging process) is preferably performed. The aging process allows the material to take up water in the environment and become particles, so that the particle containing layer (uneven layer) consisting of uniformly distributed particles can be easily formed. As a result, the resulting functional film has excellent properties. In other words, when water is included in the formed inorganic salt, the surface of the particle containing layer becomes granulated, and a finer uneven structure is formed.

Aging Step is preferably performed in the range of 1 second to 1 week.

### <Step (III) of Forming Coating Layer or Coating Film>

Step (III) of forming the coating layer or coating film is the step of forming the coating layer or coating film by the dry process on the bumpy portion or the uneven layer after Aging Step (II).

Specifically, as shown in FIG. 4F, after Aging Step (II), a coating layer 5 is formed on the particle containing layer 42 by the dry process.

As for the dry process to form the coating layer with the material depending on the type of functional film, the IAD method and the like are preferably used as described above.

The coating layer 5 is formed on the particle containing layer 42 in this way, so that the functional film 100 of the present invention having a porous with pores 5c and a fine uneven structure on the surface can be obtained.

### <Step (IV) of Storage in High Temperature and High Humidity Environment>

Step (IV) of storing the formed functional film in the high temperature and high humidity environment is the step of storing the functional film formed as described above in the high temperature and high humidity environment to reduce the anionic components contained in the film.

The high temperature and high humidity environment is, for example, an environment where the temperature is in the range of 50 to 110° C. and the humidity is in the range of 50 to 95% RH. Time of storage is preferably from 0.5 to 300 hours.

Such Step (IV) reduces the anionic component in the functional film, thereby improving its hydrophilicity.

Examples of the anionic component include Cl ions (chloride ions) and F ions (fluoride ions).

The anionic component can be checked by analyzing the composition of the functional film using an X-ray photoelectron spectroscopy (XPS) device, as described above.

### <Step (V) of Exposing Film to Environment Containing Etching Gas>

Step (V) of exposing the film to an environment containing etching gas is the step of exposing the functional film formed as described above to the environment containing the etching gas to adjust the size of gaps through which the active chemical species generated by the photocatalyst reaction can pass.

The etching gas is, for example, HF gas (hydrogen fluoride gas).

The functional film is preferably left in the environment containing such an etching gas for 1 to 60 minutes.

Etching usually means scraping a sample surface by chemically and physically attacking the sample surface with a plasma-activated etching gas. However, because the colliding molecules also act as an abrasive in such etching, the surface becomes smooth and the pores at an atomic level are blocked. On the other hand, exposure to the environment containing etching gas in the Step (V) can expand the pores by the corrosive gas that has entered the pores, without blocking the gaps. This allows to obtain a more porous structure and to further increase the passing efficiency of the photocatalyst.

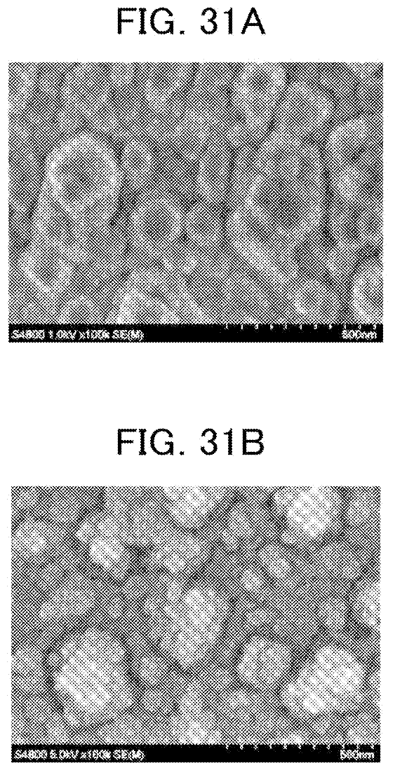

FIG. 31A and FIG. 31B are respectively images of functional films before (FIG. 31A) and after (FIG. 31B) exposure to HF gas for 30 minutes after formation observed by an electron microscope (S-4800 manufactured by Hitachi High-Tech Science Corporation) at 100,000 magnification.

As shown in FIG. 31A and FIG. 31B, it is recognized that exposure to HF gas as the etching gas makes the structure more porous.

FIG. 5A to FIG. 5C are process diagrams showing an example of the production method of the functional film shown in FIG. 2. The production method is similar to the production method shown in FIG. 4A to FIG. 4F above except that the intermediate layer is not formed, so the explanation is omitted.

### [Applications of Functional Film]

The functional film of the present invention has various functions depending on the layer configuration of the functional film. For example, when a hydrophilic layer is applied as the coating layer, it can function as a hydrophilic functional film. When a water-repellent layer is applied as the coating layer, it can function as a water-repellent functional film. When an anti-fog layer is applied as the coating layer, it can function as an anti-fog functional film. When the coating layer does not function as an anti-reflective layer or photocatalytic layer, but only as a protective layer, the functional film consisting of the base material, uneven layer, and coating layer functions as an anti-reflective functional film.

### <Optical Device>

The functional film of the present invention can be applied to an optical device.

Preferred examples of optical device include lenses, cover glass for lenses, antimicrobial cover members, antifungal coating members, or mirrors. The functional film of the present invention is suitable for automotive lenses, communication lenses, antibacterial lenses for endoscopes, members of PCs and smartphones, antibacterial cover members, glasses, ceramics for toilets and dishes, anti-mold coating for baths and sinks, or building materials (windows). Among them, it is especially suitable for automotive lenses.

The base material of the optical device to which the functional film of the present invention is applied is preferably glass from the viewpoint of transparency, and the coating layer of such a functional film is preferably the hydrophilic layer or the anti-fog layer described above. In other words, the main component of the coating layer is preferably SiO₂, which is a Si-containing material, from the viewpoint of easily obtained hydrophilic property.

The water repellent layer may be applied to the coating layer, in which case the main component contained in the coating layer is preferably a water repellent material based on fluorine or silicon.

### <Inkjet Head>

The functional film of the present invention can also be applied to an inkjet head.

The base material of the inkjet head to which the functional film of the present invention is applied is preferably silicon from the viewpoint of durability and processing characteristics. The main component of the inorganic material contained in the coating layer of the functional film is preferably SiC from the viewpoint of ink wipeability.

### <Mold>

The functional film of the present invention can also be applied to a mold.

The base material of the mold to which the functional film of the present invention is applied is preferably SiC or ultra-hard alloy from the viewpoint of strength. The main component of the inorganic material contained in the coating layer of the functional film is preferably SiC, which is a Si-containing material, from the viewpoint of strength.

### EXAMPLES

In the following examples, the present invention will be described in detail, but is not limited to these examples. In the following examples, unless otherwise noted, the operations were performed at room temperature (25° C.). Unless otherwise noted, “%” and “part” mean “% by mass” and “part by mass,” respectively.

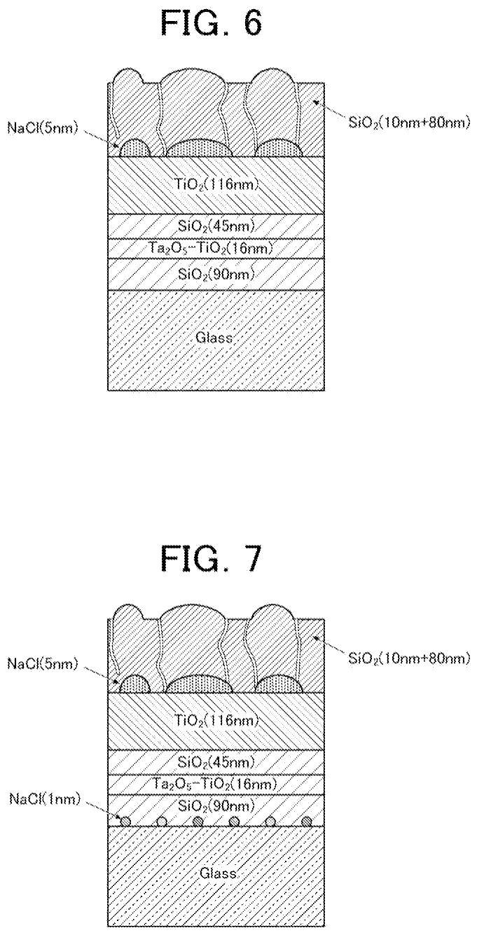

Functional films 1 to 15 respectively having the configurations shown in FIG. 6 to FIG. 20 were produced.

In the formation of each of the following layers, when the same device is used as in the previous and following processes, the layers are assumed to be formed continuously without being exposed to the atmosphere, unless otherwise noted. When a device different from those in the preceding and following processes is used, it is assumed to be exposed to the atmosphere.

### [Production of Functional Film 1] (see FIG. 6)

### <Preparation of Base Material>

Super White Glass substrate (refractive index: 1.523, manufactured by Schott AG) was prepared as the base material. This glass substrate was cleaned for 600 seconds using a UV ozone device (manufactured by Technovision, Inc.).

### <Formation of Reflectance Adjustment Layer>

### (Formation of First Low Refractive Index Layer)

On the base material, a first low refractive index layer containing SiO₂ (SiO₂ layer, 90 nm in thickness) was formed using an IAD Vacuum Coating Machine (BIS-1300DNN, manufactured by Shincron Co., Ltd.) under the following conditions.

### <<Conditions in Chamber>>

Heating temperature: 370° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the first low refractive index layer: SiO₂ (Product Name: SiO₂, manufactured by Canon Optron, Inc.)

The base material was installed in the IAD Vacuum Coating Machine, SiO₂ was loaded as the layer forming material in a first evaporation source, and the first low refractive index layer (SiO₂ layer) having a thickness of 90 nm was formed by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar. (sccm: standard cubic centimeter per minute, 1 sccm=1.69×10⁻³ Pa·m³/sec) (Formation of High Refractive Index Layer)

On the first low refractive index layer, a high refractive index layer (Ta₂O₅—TiO₂, 16 nm in thickness) was formed continuously using the IAD IAD Vacuum Coating Machine (BIS-1300DNN, manufactured by Shincron Co., Ltd.) under the following conditions.

### <<Conditions in Chamber>>

Heating temperature: 370° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the high refractive index layer: Ta₂O₅—TiO₂, (Product Name: OA-600, manufactured by Canon Optron, Inc.)

The above layer forming material was loaded in a second evaporation source of the IAD Vacuum Coating Machine, and the high refractive index layer having a thickness of 16 nm was formed by vapor deposition at a deposition rate of 4 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar. At this time, gas control was performed to keep the chamber pressure at 2×10⁻² Pa by introducing O₂ gas from an automatic pressure controller (hereinafter abbreviated as “APC”).

### (Formation of Second Low Refractive Index Layer)

On the high refractive index layer, a second low refractive index layer (SiO₂ layer, 45 nm in thickness) was formed continuously using the IAD Vacuum Coating Machine (BIS-1300DNN, manufactured by Shincron Co., Ltd.) under the following conditions.

### <<Conditions in Chamber>>

Heating temperature: 370° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the second low refractive index layer: SiO₂ (Product Name: SiO₂, manufactured by Canon Optron, Inc.)

SiO₂ was loaded as the layer forming material in the first evaporation source of the IAD Vacuum Coating Machine, and the second low refractive index layer having a thickness of 45 nm was formed on the high refractive index layer by vapor deposition at a deposition rate of 3 Å/sec.

IAD was performed at an acceleration voltage of 1,000 V, acceleration current of 1,000 mA, suppressor voltage of 500 V, and neutralization current of 1,500 mA, and the IAD introduction gas was 50 sccm of O₂, 0 sccm of Ar gas, and 10 sccm of neutral gas Ar.

### <Formation of Photocatalytic Layer>

On the second low refractive index layer, a photocatalytic layer layer (TiO₂ layer, 116 nm in thickness) was formed continuously using the IAD Vacuum Coating Machine (BIS-1300DNN, manufactured by Shincron Co., Ltd.) under the following conditions.

### <<Conditions in Chamber>>

Heating temperature: 370° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the photocatalytic layer: TiO₂ (Product Name: TOP (Ti₃O₅), manufactured by Fuji Titanium Industry Co., Ltd.)

The above layer forming material was loaded in a third evaporation source of the IAD Vacuum Coating Machine, and the photocatalytic layer having a thickness of 116 nm was formed on the second low refractive index layer by vapor deposition at a deposition rate of 2 Å/sec.

IAD was performed at an acceleration voltage of 300 V, acceleration current of 300 mA, suppressor voltage of 1000 V, and neutralization current of 600 mA, and the IAD introduction gas was 50 sccm of O₂, 10 sccm of Ar gas, and 10 sccm of neutral gas Ar. At this time, gas control was performed to keep the chamber pressure at 3×10⁻² Pa by introducing O₂ gas from the APC.

### <Formation of Uneven Layer (Particle Containing Layer)>

After the photocatalytic layer was formed, the substrate was taken out of the IAD Vacuum Coating Machine and placed in the deposition device, and a particle containing layer (NaCl layer, 5 nm in thickness) was formed on the photocatalytic layer.

A deposition device (BMC-800T, manufactured by Shincron Co., Ltd.) was used for resistance heating vapor deposition of NaCl under the following conditions.

### <<Conditions in Chamber>>

Heating temperature: 25° C.

Starting vacuum: 5.0×10⁻³ Pa

Deposition rate: 1 Å/sec.

Next, the substrate was once opened to the atmosphere to particulate the NaCl, and a particle containing layer with unevenness was obtained.

### <Formation of Coating Layer (Hydrophilic Layer)>

After forming the particle containing layer, the substrate was placed in the IAD Vacuum Coating Machine (BIS-1300DNN, manufactured by Shincron Co., Ltd.), and a hydrophilic layer composed of two layers (SiO₂ layer (10 nm in thickness) and SiO₂ layer (80 nm in thickness)) was formed on the particle containing layer.

On the particle containing layer, the SiO₂ layer (10 nm in thickness) was formed using the IAD Vacuum Coating Machine (BIS-1300DNN, manufactured by Shincron Co., Ltd.) under the following conditions.

### <<Conditions in Chamber>>

Heating temperature: 30° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the hydrophilic layer: SiO₂ (Product Name: SiO₂, manufactured by Canon Optron, Inc.)

SiO₂ was loaded as the layer forming material in the first evaporation source of the IAD Vacuum Coating Machine, and the SiO₂ layer having a thickness of 10 nm was formed on the particle containing layer by vapor deposition at a deposition rate of 3 Å/sec.

IAD was performed at an acceleration voltage of 1,000 V, acceleration current of 1,000 mA, suppressor voltage of 500 V, and neutralization current of 1,500 mA, and the IAD introduction gas was 50 sccm of O₂, 0 sccm of Ar gas, and 10 sccm of neutral gas Ar.

Next, the SiO₂ layer having a thickness of 80 nm was formed under the same conditions except that the IAD was turned off.

Functional film 1 was obtained by the above processes.

In the production of the functional film 1, the reflectance adjustment layer, photocatalytic layer, and hydrophilic layer were formed using the same machine (BIS-1300DNN, manufactured by Shincron Co., Ltd.), and only the particle containing layer was formed using a different machine (BMC-800T, manufactured by Shincron Co., Ltd.)

### [Production of Functional Film 2] (see FIG. 7)

A functional film 2 was produced in the same way as the functional film 1, except that an uneven layer (particle containing layer) (NaCl layer, 1 nm in thickness) was further formed between the base material and the reflectance adjustment layer in the following manner.

### <Formation of Uneven Layer (Particle Containing Layer)>

The deposition device (BMC-800T, manufactured by Shincron Co., Ltd.) was used for resistance heating vapor deposition of NaCl under the following conditions.

### <<Conditions in Chamber>>

Heating temperature: 25° C.

Starting vacuum: 5.0×10⁻³ Pa

Deposition rate: 1 Å/sec.

Next, the substrate was once opened to the atmosphere to particulate the NaCl, and a particle containing layer with unevenness (NaCl layer, 1 nm in thickness) was obtained.

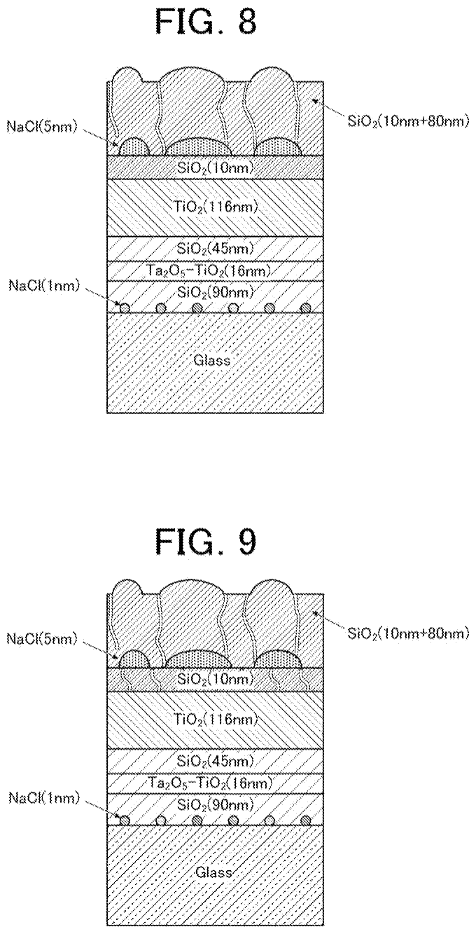

### [Production of Functional Film 3] (see FIG. 8)

A functional film 3 was produced in the same way as the functional film 2, except that an uneven layer (intermediate layer) (SiO₂ layer, 10 nm in thickness) was further formed between the photocatalytic layer and the particle containing layer (NaCl layer, 5 nm in thickness) in the following manner.

### <Formation of Uneven Layer (Intermediate Layer)>

On the photocatalytic layer, an intermediate layer containing SiO₂ (SiO₂ layer) was formed using the IAD Vacuum Coating Machine (BIS-1300DNN, manufactured by Shincron Co., Ltd.) under the following conditions.

### <<Conditions in Chamber>>

Heating temperature: 30° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the hydrophilic layer: SiO₂ (Product Name: SiO₂, manufactured by Canon Optron, Inc.)

SiO₂ was loaded as the layer forming material in the first evaporation source of the IAD Vacuum Coating Machine, and the intermediate layer (SiO₂ layer) having a thickness of 10 nm was formed on the photocatalytic layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

### [Production of Functional Film 4] (see FIG. 9)

A functional film 4 was produced in the same way as the functional film 3, except that the intermediate layer was etched in the following manner.

### <Etching of Uneven Layer (Intermediate Layer)>

An Ag mask was formed on the intermediate layer that was formed in the same manner as the functional film 3. The Ag mask was formed using the deposition device (BMC-800T, manufactured by Shincron Co., Ltd.) under the following conditions. The thickness of the Ag mask was 20 nm.

### <<Conditions in Chamber>>

Heating temperature: 180° C.

Starting vacuum: 5.0×10⁻³ Pa

Deposition rate: 3 Å/sec.

After the Ag mask was formed, etching was performed under the following conditions using CE-300I (manufactured by ULVAC, Inc.) as an etching machine. The depth and average diameter of the dents in the intermediate layer were adjusted by changing the etching time.

### <<Etching Conditions>>

Antenna RF: 400 W

Bias RF: 38 W

APC pressure: 0.5 Pa

CHF₃ flow rate: 20 sccm

Total etching time: 30 seconds

### <<Removal of Ag Mask>>

After the dents were formed, the sample was immersed in Pure Etch Au100 (manufactured by Hayashi Pure Chemical Ind., Ltd.) for 5 seconds, and the Ag mask was removed. The samples were then ultrasonically washed in pure water and cleaned with a UV ozone device (Technovision, Inc.) for 600 seconds.

### [Production of Functional Film 5] (see FIG. 10A and FIG. 10B)

A functional film 5 was produced in the same way as the functional film 2 until the formation of the particle containing layer (NaCl layer (5 nm in thickness)), and then the following changes were made.

### <Formation of Particle Containing Layer and Coating Layer (Hydrophilic Layer)>

After the particle containing layer (NaCl layer (5 nm in thickness)) was formed on the photocatalytic layer, the substrate was taken out of the deposition device and exposed to the atmosphere. After that, the substrate was placed in the following IAD Vacuum Coating Machine, and eight units U were stacked on the particle containing layer (NaCl layer (5 nm in thickness)). The units U each consist of a NaCl layer (1 nm thickness), a SiO₂ layer (1 nm in thickness), and a SiO₂ layer (5 nm in thickness) stacked in this order. A plurality of particle containing layers and hydrophilic layers were thereby formed.

FIG. 10B shows the details of the uppermost layer (the layer labeled “SiO₂+NaCl”) in FIG. 10A. The detailed procedure is described below.

### (Formation of NaCl Layer (1 nm in Thickness))

The NaCl layer (1 nm in thickness) was formed by deposition of NaCl on the particle containing layer (NaCl layer (5 nm in thickness)) by vapor deposition at a deposition rate of 1 Å/sec using the IAD Vacuum Coating Machine (BIS-1300DNN, manufactured by Shincron Co., Ltd.) under the following conditions.

### <<Conditions in Chamber>>

Heating temperature: 30° C.

Starting vacuum: 5.0×10⁻³ Pa

### <<Evaporation Source of Layer Forming Material>>

Electron gun

### (Formation of SiO₂ Layer (1 nm in Thickness))

Next, the SiO₂ layer (1 nm in thickness) was formed on the NaCl layer (1 nm in thickness).

### <<IAD Ion Source>>

RF ion source NIS-175-3 (manufactured by Shincron Co., Ltd.)

Material for forming the SiO₂ layer: SiO₂ (Product Name: SiO₂, manufactured by Canon Optron, Inc.)

SiO₂ was loaded as the layer forming material in the first evaporation source of the IAD Vacuum Coating Machine that was continuously used, and the SiO₂ layer having a thickness of 1 nm was formed on the NaCl layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

### (Formation of SiO₂ Layer (5 nm in Thickness))

Next, the SiO₂ layer (5 nm in thickness) was formed on the SiO₂ layer (1 nm in thickness).

The SiO₂ layer (5 nm in thickness) was formed in the same manner as the formation of the SiO₂ layer (1 nm in thickness) except that the IAD was turned off.

The above formation of the unit U consisting of the NaCl layer (1 nm in thickness), the SiO₂ layer (1 nm in thickness), and the SiO₂ layer (5 nm in thickness) was assumed to be one set, which was repeated eight times until the functional film 5 was obtained.

At the time of forming the SiO₂ layer (1 nm in thickness) after formation of the NaCl layer (1 nm in thickness) in the unit U, the NaCl layer (1 nm in thickness) is difficult to be particulate and easily peels off because the NaCl layer (1 nm in thickness) has not been exposed to the atmosphere. Therefore, the SiO₂ layer (1 nm in thickness) was formed using IAD so that the adhesion of the NaCl layer (1 nm thick) is good. On the other hand, in the formation of the SiO₂ layer (5 nm in thickness), IAD was not used to form a porous layer. In this way, the SiO₂ layer (1 nm in thickness) formed subsequent to the NaCl layer was formed using IAD in terms of adhesion, and other layer was formed without using IAD so as to be porous.

The composition analysis of the obtained functional film 5 was performed from measurement results using the following X-ray photoelectron spectroscopy (XPS) under the following conditions. The measurement results are shown in FIG. 26A and FIG. 26B. FIG. 26A shows the measurement results immediately after formation, and FIG. 26B shows the measurement results after the film was left in a high temperature and high humidity environment of 85° C. and 85% RH for 300 hours.

Name of device: X-ray Photoelectron Spectrometer (XPS)

Model: Quantera SXM

Device manufacturer: ULVAC-PHI, Inc.

Measurement conditions: X-ray source: Monochromatized AlKα beam 25 W-15 kV

Degree of vacuum: 5.0×10⁻⁸ Pa

Analysis of depth profiles was performed by argon ion etching. Data were processed using analysis software MultiPak (manufactured by ULVAC-PHI, Inc.).

These results reveal that the amounts of Na and Cl are the maximum where NaCl (5 nm in thickness) is present, and it is possible to identify the presence of an uneven layer of NaCl at this position. Since NaCl (1 nm in thickness) is formed continually, Na is present at a certain amount throughout the coating layer, which is responsible for maintaining hydrophilicity at high temperature and high humidity. The results after the film was left in a high temperature and high humidity environment of 85° C. and 85% RH for 300 hours reveal that Cl has almost disappeared. Since the composition and distribution can be adjusted in the high temperature and humidity environment in this way, the composition of the inorganic salts forming the unevenness can be fine-tuned after completion of the film formation, depending on the required functions. This environment for composition adjustment is not limited to this.

### [Production of Functional Film 6] (see FIG. 11A and FIG. 11B)

A functional film 6 was produced in the same way as the functional film 3, except that the coating layer (hydrophilic layer) was changed as follows.

### <Formation of Coating Layer (Hydrophilic Layer)>

After the particle containing layer (NaCl layer, 5 nm in thickness) was formed, the substrate was taken out of the deposition device and exposed to the atmosphere. After that, the substrate was placed in the following IAD Vacuum Coating Machine, a SiO₂ layer (10 nm in thickness) was formed using IAD method on the particle containing layer (NaCl layer, 5 nm in thickness), and then four units U were stacked. The units U each consist of a TiO₂ layer (1 nm in thickness) and a SiO₂ layer (10 nm in thickness) stacked in this order. A hydrophilic layer was thereby formed.

FIG. 11B shows the details of the uppermost layer (the layer labeled “SiO₂+TiO₂”) in FIG. 11A. The detailed procedure is described below.

### (Formation of SiO₂ Layer (10 nm in Thickness))

The SiO₂ layer (10 nm in thickness) was formed by deposition on the particle containing layer (NaCl layer (5 nm in thickness)) using the IAD Vacuum Coating Machine (BIS-1300DNN, manufactured by Shincron Co., Ltd.) under the following conditions.

### <<Conditions in Chamber>>

Heating temperature: 30° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the hydrophilic layer: SiO₂ (Product Name: SiO₂, manufactured by Canon Optron, Inc.)

SiO₂ was loaded as the layer forming material in the first evaporation source of the IAD Vacuum Coating Machine, and the hydrophilic layer (SiO₂ layer) having a thickness of 10 nm was formed on the particle containing layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

### (Formation of TiO₂ Layer (1 nm in Thickness))

Next, the TiO₂ layer (1 nm in thickness) was formed on the SiO₂ layer (10 nm in thickness).

On the SiO₂ layer (10 nm in thickness), the TiO₂ layer was formed continuously using the IAD Vacuum Coating Machine (BIS-1300DNN, manufactured by Shincron Co., Ltd.) under the following conditions.

### <<Conditions in Chamber>>

Heating temperature: 370° C.

Starting vacuum: 5.0×10⁻³ Pa

### <<Evaporation Source of Layer Forming Material>>

Electron gun

### <<IAD Ion Source>>

RF ion source NIS-175-3 (manufactured by Shincron Co., Ltd.)

Material for forming the photocatalytic layer: TiO₂ (Product Name: TOP (Ti₃O₅), manufactured by Fuji Titanium Industry Co., Ltd.)

The above layer forming material was loaded in the third evaporation source of the IAD Vacuum Coating Machine, and the TiO₂ layer having a thickness of 1 nm was formed on the SiO₂ layer (10 nm in thickness) by vapor deposition at a deposition rate of 2 Å/sec.

IAD was performed at an acceleration voltage of 300 V, acceleration current of 300 mA, suppressor voltage of 1000 V, and neutralization current of 600 mA, and the IAD introduction gas was 50 sccm of O₂, 10 sccm of Ar gas, and 10 sccm of neutral gas Ar. At this time, gas control was performed to keep the chamber pressure at 3×10⁻² Pa by introducing O₂ gas from the APC.

### (Formation of SiO₂ Layer (10 nm in Thickness))

Next, the SiO₂ layer (10 nm in thickness) was formed on the TiO₂ layer (1 nm in thickness).

The SiO₂ layer (10 nm in thickness) was formed in the same manner as the formation of the SiO₂ layer (10 nm in thickness) that was formed on the particle containing layer (NaCl layer, 5 nm in thickness) except that the IAD was turned off.

The above formation of the unit U consisting of the TiO₂ layer (1 nm in thickness) and the SiO₂ layer (10 nm in thickness) was assumed to be one set, which was repeated four times after formation of the SiO₂ layer (10 nm in thickness) using the IAD until the functional film 6 was obtained.

The TiO₂ layer (1 nm in thickness) and SiO₂ layer (10 nm in thickness) were alternately stacked in the units U above because stacking layers made of different components makes the film more porous.

### [Production of Functional Film 7] (See FIG. 12)

A functional film 7 was produced in the same way as the functional film 1, except that, of the two hydrophilic layers (SiO₂ layer (10 nm in thickness) and SiO₂ layer (80 nm in thickness)) composing the coating layer, the upper SiO₂ layer was formed to be a thickness of 110 nm, and a water repellent layer (25 nm in thickness) as shown below was further formed on the formed SiO₂ layer (110 nm in thickness).

### <Formation of Water Repellent Layer>

The water repellent layer (25 nm in thickness) was formed by deposition of SURFCLEAR 100 (manufactured by Canon Optron, Inc.) on the SiO₂ layers (10 nm+110 nm in thickness) by vapor deposition at a deposition rate of 1 Å/sec using Optical Thin Film Coater (Gener-1300, manufactured by Optorun Co., Ltd.). The deposition conditions were as follows.

### <<Conditions in Chamber>>

Material for forming the water repellent layer: SURFCLEAR 100 (manufactured by Canon Optron, Inc.) (indicated as “SC100” in FIG. 12)

Heating temperature: No heating (room temperature)

Starting vacuum: 2.0×10⁻³ Pa

### <<Evaporation Source of Layer Forming Material>>

Resistance heating

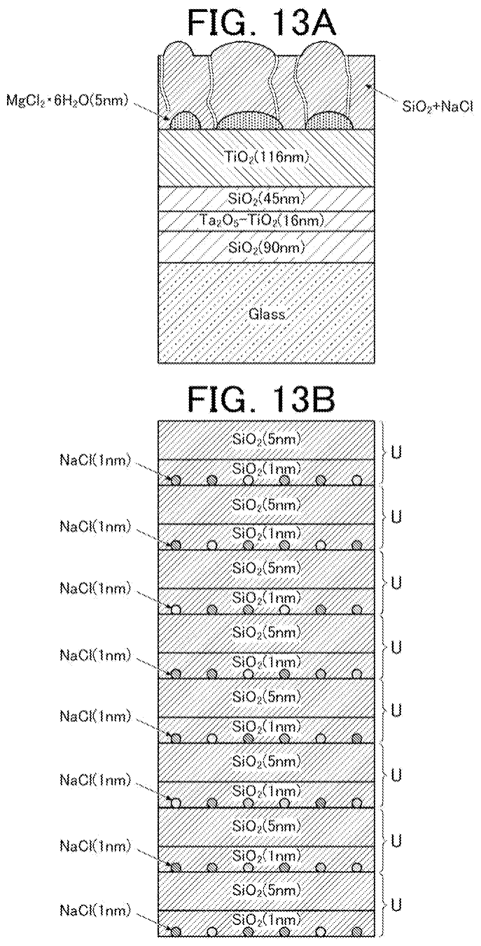

The water repellent layer obtained in this way had an initial water contact angle of 131 degrees. [Production of Functional Film 8] (see FIG. 13A and FIG. 13B)

A functional film 8 was produced in the same way as the functional film 5, except that the NaCl layer (1 nm in thickness) (particle containing layer) between the base material and the reflectance adjustment layer was not formed, and that a MgCl₂-6H₂O layer (5 nm in thickness) shown below was formed instead of the NaCl layer (5 nm in thickness) (particle containing layer) between the photocatalytic layer and the hydrophilic layer.

FIG. 13B shows the details of the uppermost layer (the layer labeled “SiO₂+NaCl”) in FIG. 13A. The detailed procedure is described below.

<Formation of MgCl₂.6H₂O Layer>

On the photocatalytic layer, a MgCl₂-6H₂O layer was formed. The MgCl₂-6H₂O layer having a thickness of 5 nm was formed using the deposition device (BMC-800T, manufactured by Shincron Co., Ltd.) by resistance heating deposition under the following conditions.

### <<Conditions in Chamber>>

Heating temperature: 25° C.

Starting vacuum: 5.0×10⁻³ Pa

Deposition rate: 1 Å/sec.

Next, the substrate was once opened to the atmosphere to particulate the MgCl₂-6H₂O, and a particle containing layer (MgCl₂-6H₂O layer, 5 nm in thickness) with unevenness was obtained.

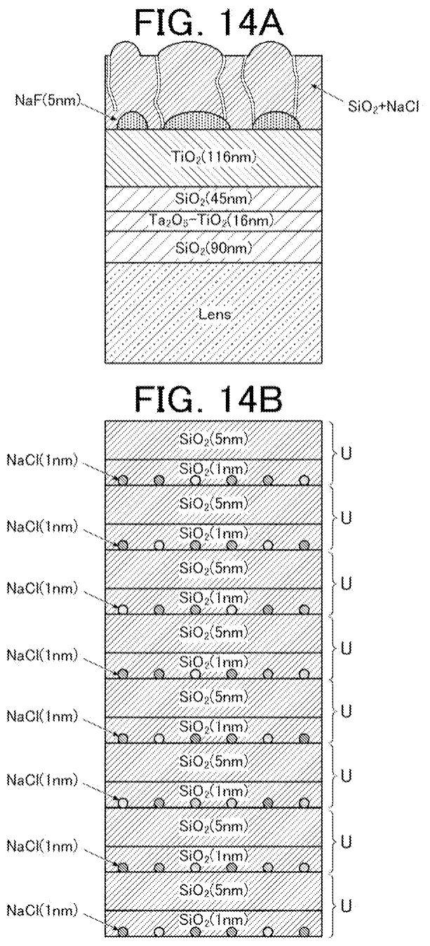

### [Production of Functional Film 9] (see FIG. 14A and FIG. 14B)

A functional film 9 was produced in the same way as the functional film 5, except that the NaCl layer (1 nm in thickness) (particle containing layer) between the base material and the reflectance adjustment layer was not formed, and that a NaF layer (5 nm in thickness) shown below was formed instead of the NaCl layer (5 nm in thickness) (particle containing layer) between the photocatalytic layer and the hydrophilic layer.

The lens used as the base material was made of glass material TAFD5G (manufactured by HOYA Corporation) processed for an automotive lens.

FIG. 14B shows the details of the uppermost layer (the layer labeled “SiO₂+NaCl”) in FIG. 14A. The detailed procedure is described below.

### <Formation of NaF Layer>

On the photocatalytic layer, a NaF layer was formed. The NaF layer having a thickness of 5 nm was formed using the deposition device (BMC-800T, manufactured by Shincron Co., Ltd.) by resistance heating vapor deposition under the following conditions.

### <<Conditions in Chamber>>

Heating temperature: 25° C.

Starting vacuum: 5.0×10⁻³ Pa Deposition rate: 1 Å/sec.

Next, the substrate was once opened to the atmosphere to particulate the NaF, and a particle containing layer (NaF layer, 5 nm in thickness) with unevenness was obtained.

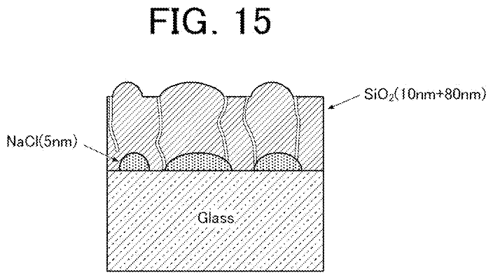

### [Production of Functional Film 10] (see FIG. 15)

A functional film 10 was produced in the same way as the functional film 1, except that no reflectance adjustment layer or photocatalytic layer was formed.

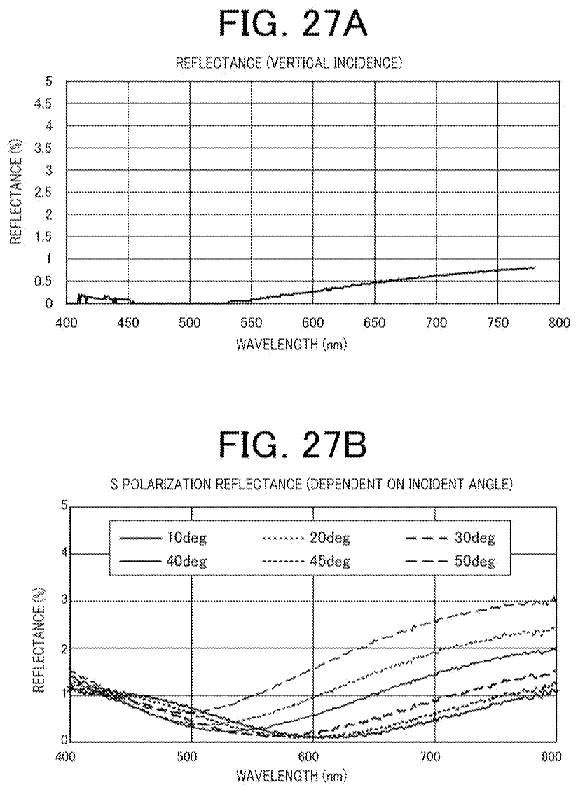

FIG. 27A and FIG. 27B show graphs of the reflection property of the functional film 10. As shown in FIG. 27A and FIG. 27B, the functional film 10 exhibits good reflective properties (1% or less for vertical incidence and 3% or less even for 50° incidence of S-polarized light).

### [Production of Functional Film 11] (see FIG. 16A and FIG. 16B)

A functional film 11 was produced in the same way as the functional film 9, except that a plurality of NaCl layers (1 nm in thickness) between the hydrophilic layers (SiO₂ layers (1 nm in thickness) and SiO₂ layers (5 nm in thickness)) was changed to a plurality of NaF layers (1 nm in thickness), and a PET film was used as the base material. The PET film used as the base material was KB film (manufactured by Kimoto Co., Ltd.).

FIG. 16B shows the details of the uppermost layer (the layer labeled “SiO₂+NaF”) in FIG. 16A.

### [Production of Functional Film 12] (see FIG. 17A and FIG. 17B)

In the production of the above functional film 11, the NaF layer (5 nm in thickness) on the photocatalytic layer was changed to a NaCl layer (5 nm in thickness), and the NaF layers (1 nm in thickness) between the hydrophilic layers (SiO₂ layer (1 nm in thickness) and SiO₂ layer (5 nm in thickness)) were changed to NaCl layers (1 nm in thickness). As a result, the NaCl layer (5 nm in thickness) (the first uneven layer) was formed on the photocatalytic layer, and first eight units U each consisting of a NaCl layer (1 nm in thickness), SiO₂ layer (1 nm in thickness), and SiO₂ layer (5 nm in thickness) were formed on the NaCl layer (5 nm in thickness).

After that, a NaCl layer (5 nm in thickness) (second uneven layer) was further formed using the BMC-800T (manufactured by Shincron Co., Ltd.). After that, second eight units U each consisting of a NaCl layer (1 nm in thickness), SiO₂ layer (1 nm in thickness), and SiO₂ layer (5 nm in thickness) were formed using the BMC-800T (manufactured by Shincron Co., Ltd.), and the functional film 12 was produced.

Thus, the functional film 12 has two stacked structures K on the photocatalytic layer. The stacked structures K each consist of the NaCl layer (5 nm in thickness) and eight units U each consisting of the NaCl layer (1 nm in thickness), SiO₂ layer (1 nm in thickness), and SiO₂ layer (5 nm in thickness).

The more stacked structures K are formed, the more the maximum height of the bumps increases, and the more the anti-fog effect is exhibited.

FIG. 17B shows the details of the uppermost layer (the layer labeled “SiO₂+NaCl” in FIG. 17A) and one layer below the uppermost layer (the layer labeled “SiO₂+NaCl” in FIG. 17A) in FIG. 17A.

The NaCl layer (5 nm in thickness) (second uneven layer) was formed between the stacked structures K because stacking the NaCl layer (5 nm in thickness) having a different thickness from the NaCl layer (1 nm in thickness) amplifies the unevenness and makes the film more porous.

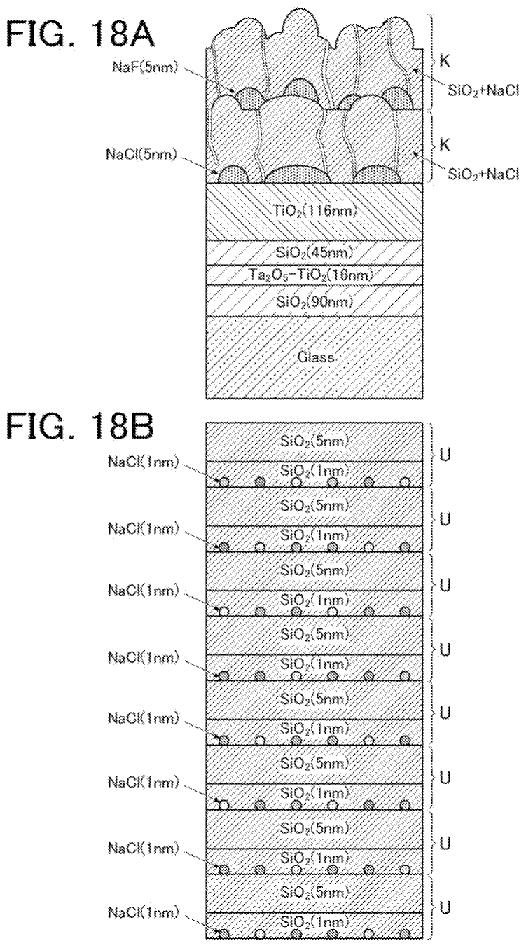

### [Production of Functional Film 13] (see FIG. 18A and FIG. 18B)

A functional film 13 was produced in the same way as the functional film 12, except that the second uneven layer (NaCl layer, 5 nm in thickness) (NaCl layer between the first eight units U and the second eight units U) was changed to a NaF layer.

The layer composition of functional film 13 was chosen for the following reasons. The particles of NaF are smaller in diameter compared to the particles of NaCl. The spaces between particles are also smaller for NaF particles compared to NaCl particles. Therefore, the effect of increasing the surface area can be further increased by using a NaCl layer with large particle diameters and spaces as the first uneven layer (uneven layer on the photocatalytic layer), and a NaF layer with small particle diameters and spaces as the second uneven layer.

When the first uneven layer is a NaF layer with small particle diameters and spaces, the particles will be finer, but the maximum height of the bumps is low. However, when the first uneven layer is a NaCl layer consisting of coarse particles with large particle diameters and spaces to form large bumps, the NaF layer as the second uneven layer, in spite of consisting of particles with small diameters, can form a sufficient maximum height of bumps. FIG. 18B shows the details of the uppermost layer (the layer labeled “SiO₂+NaCl” in FIG. 18A) and one layer below the uppermost layer (the layer labeled “SiO₂+NaCl” in FIG. 18A) in FIG. 18A.

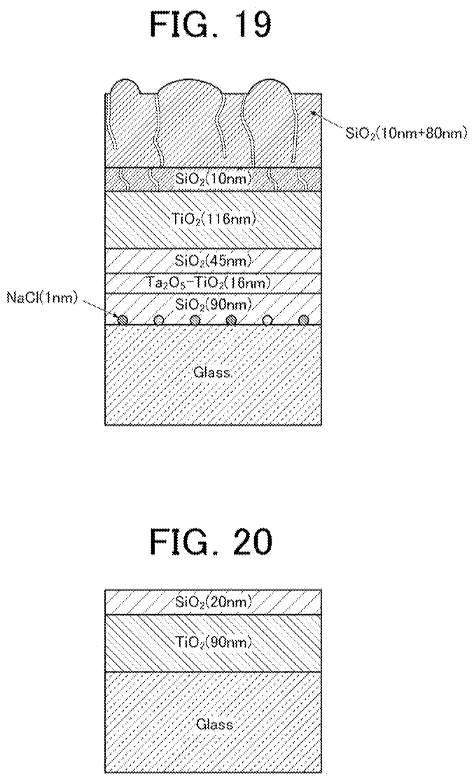

### [Production of Functional Film 14] (see FIG. 19)

A functional film 14 was produced in the same way as the functional film 4, except that the NaCl layer (5 nm in thickness) (particle containing layer) formed on the intermediate layer (SiO₂ layer (10 nm in thickness)).

### [Production of Functional Film 15] (Comparative Example) (see FIG. 20)

### <Preparation of Base Material>

A glass substrate (soda-lime glass) having the following silica film formed on it was used as the base material.

96.2 parts by mass of ethanol and 3.8 parts by mass of hydrolysis-condensation polymerization solution of ethyl silicate (product name: HAS-10, manufactured by Colcoat Co. Ltd., containing 10% by mass of silica) were mixed at room temperature and stirred for one hour to obtain a coating solution for forming an alkali-blocking silica film.

A soda-lime silicate glass plate (150×150×3 mm) was polished and cleaned on its surface with cerium oxide abrasive, ultrasonically washed in pure water, dried, and hung vertically in an environment of 20° C., 30% RH. The above coating solution for forming an alkali-blocking silica film was poured from the top of the above glass plate to coat one surface of the glass plate with a film (flow coating method). The glass plate was dried at 100° C. for 30 minutes, further dried at 250° C. for 30 minutes, and then heated in an oven at 500° C. for one hour. As a result, a glass substrate with an alkali-blocking silica film with a thickness of about 30 nm was obtained.

### <Formation of Photocatalytic Layer>

To 85.6 g (0.3 mol) of titanium tetraisopropoxide (Ti(OiPr)₄) under stirring, 60.3 g (0.6 mol) of acetylacetone (AcAc) was gradually added using a burette. The mixture was stirred for about one hour to obtain a stable Ti(AcAc)₂(OiPr)₂ complex solution (mother solution).

The mother solution was diluted 1.5 times with ethanol to be a coating solution. The above glass substrate with the silica film was immersed in the coating solution, pulled up at a speed of 4.6 cm/min so that a film was formed on it, and then baked at 500° C. for 30 minutes. As a result, a photocatalytic layer (TiO₂ layer, 90 nm in thickness) was obtained.

### <Formation of Uneven Layer (Particle Containing Layer)>

On the photocatalytic layer, the uneven layer (particle containing layer) was formed by the following method.

98.8 g of ethanol, 0.7 g of hydrolysis-condensation polymerization solution of ethyl silicate (product name: HAS-10, manufactured by Colcoat Co., Ltd., silica component: 10% by mass), and 0.5 g of chain silica colloid (product name: SNOWTEX® OUP, manufactured by Nissan Chemical Corporation, average diameter: approx. 15 nm, average length: approx. 170 nm, solid content: 15% by mass) were mixed and stirred at room temperature for about 1 hour, and the coating solution for forming the coating layer was obtained.

The substrate on which the photocatalytic layer was formed was hung vertically in an environment of 20° C., 30% RH. The above coating solution for forming the coating layer was poured from the top of the above substrate to cover the photocatalytic layer of the substrate with a film (flow coating method).

After that, the substrate was heated at 500° C. for one hour, and the uneven layer (SiO₂ layer, 20 nm in thickness) was formed.

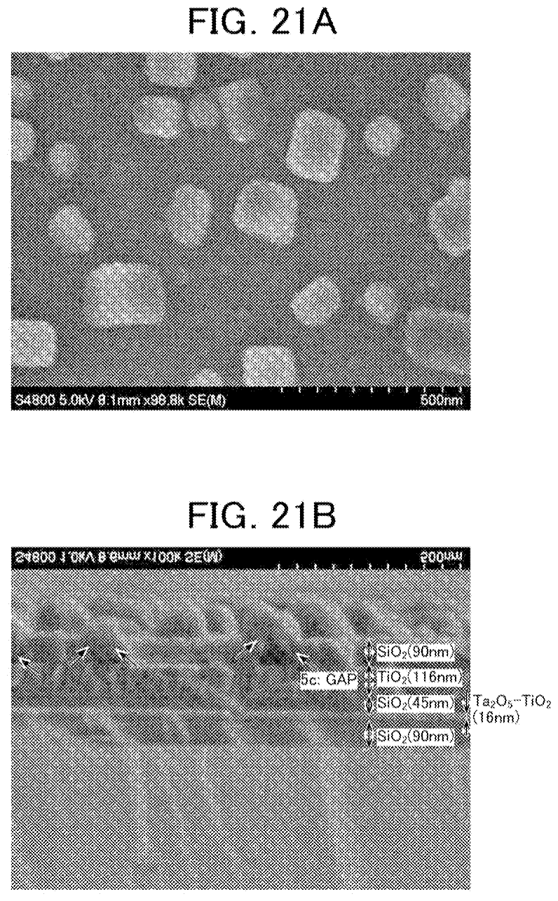

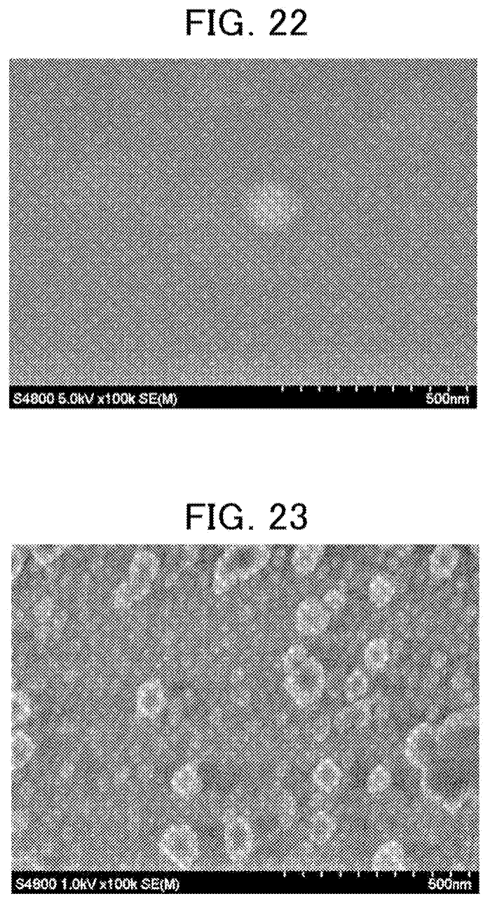

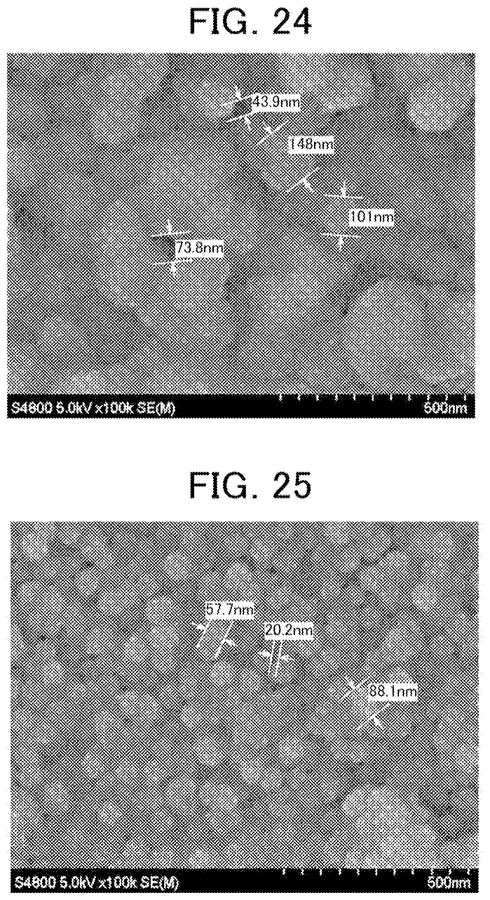

FIG. 21A to FIG. 25 are images of functional films 1, 8, 9, 12, and 13 of the functional films obtained as described above observed by an electron microscope (5-4800 manufactured by Hitachi High-Tech Science Corporation) at 100,000 magnification.

FIG. 21B is an image of a cross-section view of the functional film, and the other drawings are images of the surfaces of the functional films.

For each of the functional films 1 to 15, the average roughness Ra of the bump, the maximum height of the bump, and the average diameter of the bumps were calculated by the following method and shown in Table I. The solubility in water at 20° C. of the inorganic salts used in the particle containing layer is also shown in Table I.

### <Average Roughness Ra of Bump>

The arithmetic average roughness Ra of the bumps was the average of roughness at 10 or more portions including bumps using the atomic force microscope (L-Trace, manufactured by Hitachi High-Tech Science Corporation) as described above.

### <Maximum Height of Bump>

The maximum height of the bumps was the maximum value of heights of 10 or more bumps measured using the atomic force microscope (L-Trace, manufactured by Hitachi High-Tech Science Corporation).

### <Average Diameter of Bumps>

The average diameter of the bumps was the average of diameters of from 10 or more bumps measured using the electron microscope (S-4800 manufactured by Hitachi High-Tech Science Corporation).

The average diameter of the bumps in functional film 15 could not be measured because of their chain-like shape.

### <Presence or Absence of Diffracted Light>

Each of the functional films 1 to 15 was placed between a helium-neon laser and a screen, and light was emitted through the functional film to the screen. The presence or absence of diffracted light on the screen was visually checked.

### <Total Transmittance>

Total transmittance of each of the functional films 1 to 15 was measured using the turbidity (haze) meter NDH5000SP (manufactured by Nippon Denshoku Industries Co., Ltd.).

### [Evaluation]

<Photocatalytic Effect under High Temperature and High Humidity>

The functional films 1 to 15 were each left in a high temperature and high humidity (85° C., 85% RH) environment for 100 hours. After that, the photocatalytic effect was determined by irradiating a sample that is colored with a methylene blue ink pen with ultraviolet light at an integrated light intensity of 20 J at 20° C. and 80% RH and by evaluating the color change of the pen step by step according to the following criteria.

### (Criteria)

AA: Complete disappearance

BB: Partial disappearance and partial fading

CC: Fading

DD: No change

### <Contact Angle Under High Temperature and High Humidity>

The functional films 1 to 15 were each left in a high temperature and high humidity (85° C., 85% RH) environment for 1,000 hours. Then, 1.0 μL of pure water was dropped onto the surface of the functional film under an environment of 23° C. and 50% RH. The static contact angle measured 5 seconds after the drop using the contact angle measurement device G-1 (manufactured by ERMA Inc.) was defined as the contact angle A. The measured contact angle A was then ranked according to the following criteria.

### (Criteria)

AA: Contact angle A is less than 10⁰.

BB: Contact angle A is 10⁰ or more and less than 30°.

CC: Contact angle A is 30° or more and less than 60°.

DD: Contact angle A is 60° or more.

<Rub Resistance (Rubbing with Scourer)>

In a rub resistance test, the surface of each of the functional films 1 to 15 was rubbed with a scourer (japanese Kamenoko Tawashi) 250 times back and forth with a load of 2 kg. Reflectance was measured using the procedure described below. The optical reflectance change was calculated from the average reflectance before and after rubbing. The rub resistance was evaluated according to the following criteria.

### (Criteria)

AA: Optical reflectance change is less than 2.0%.

BB: Optical reflectance change is 2.0% or more and less than 4.0%.

CC: Optical reflectance change is 4.0% or more and less than 6.0%.

DD: Optical reflectance change is 6.0% or more.

### <Reflectance>

The average optical reflectance within the wavelength range of 450 to 780 nm of each of the functional films 1 to 15 was measured using a micro spectrophotometer (USPM-RU, manufactured by Olympus Corporation). The obtained average reflectance was evaluated according to the following criteria. When the evaluation result was AA, BB, or CC, the film was judged to be acceptable for practical use.

### (Criteria)

AA: Average optical reflectance is less than 3.0%.

BB: Average optical reflectance is 3.0% or more and less than 5.0%.

CC: Average optical reflectance is 5.0% or more and less than 8.0%.

DD: Average optical reflectance is 8.0% or more.

TABLE 1

| | | | | | | | | Maximum | Average | | |
|---|---|---|---|---|---|---|---|---|---|---|---|
| | | Particle | | | | | | Height | Diameter | | |
| | Base | Containing | | | Coating | | | of Bump | of Bump | | Intermediate |
| *1 | Material | Layer | *1 | *3 | Layer | *4 | *5 | (nm) | (nm) | *6 | Layer |
| 1 | **1 | NaCl | 35.9 | **2 | SiO₂ | **4 | 23 | [symbol] | 78 | TiO₂ | Absent |
| 2 | **1 | NaCl | 35.9 | **2 | SiO₂ | **4 | 19 | [symbol] | [symbol] | TiO₂ | Present |
| 3 | **1 | NaCl | 35.9 | **2 | SiO₂ | **4 | 20 | [symbol] | 52 | TiO₂ | Present |
| 4 | **1 | NaCl | 35.9 | **2 | SiO₂ | **4 | 31 | 107 | 125 | TiO₂ | Absent |
| 5 | **1 | NaCl | 35.9 | **2 | SiO₂ | **4 | 24 | [symbol] | 78 | TiO₂ | Absent |
| 6 | **1 | NaCl | 35.9 | **2 | SiO₂/TiO₂ | **4 | 28 | 93 | 83 | TiO₂ | Present |
| 7 | **1 | NaCl | 35.9 | **2 | *3 | **4 | 29 | 110 | 95 | TiO₂ | Absent |
| 8 | **1 | [symbol] | 54.3 | **2 | SiO₂ | **4 | 11 | 85 | 94 | TiO₂ | Absent |
| | | 6H₂O | | | | | | | | | |
| 9 | [symbol] | NaF | 4.08 | **2 | SiO₂ | **4 | 3 | 38 | 86 | TiO₂ | Absent |
| 10 | **1 | NaCl | 35.9 | **2 | SiO₂ | **4 | [symbol] | 155 | 108 | TiO₂ | Absent |
| 11 | [symbol] | NaF | 4.08 | **2 | SiO₂ | **4 | 2 | 24 | 75 | TiO₂ | Absent |
| 12 | **1 | NaCl | 35.9 | **2 | SiO₂ | **4 | 40 | 257 | 175 | TiO₂ | Absent |
| 13 | **1 | NaCl and | 35.9 and | **2 | SiO₂ | **4 | 32 | 165 | 64 | TiO₂ | Absent |
| | | NaF | 4.08 | | | | | | | | |
| 14 | **1 | — | — | — | SiO₂ | **4 | 25 | 30 | [symbol] | TiO₂ | Present |
| 15 | [symbol] | SiO₂ | 0.012 | [symbol] -gel | Absent | — | 6 | 19 | Chain | TiO₂ | Absent |
| | Glass | | | Method | | | | | | | |

| | | | Photocatalyst | Contact angle | | | | |
|---|---|---|---|---|---|---|---|---|
| | | | after 100 | after 100 | | | | |
| | | | hours at High | hours at High | Rubbing | | Type of | |
| | Diffracted | | Temperature | Temperature | with a | | Functional | |
| *1 | Light | *7 | and Humidity | and Humidity | [symbol] | *8 | Film | [symbol] |
| 1 | Absent | [symbol] | BB | BB | AA | AA | **5 | Present Invention |
| 2 | Absent | [symbol] | BB | BB | AA | AA | **5 | Present Invention |
| 3 | Absent | [symbol] | CC | BB | AA | AA | **5 | Present Invention |
| 4 | Absent | [symbol] | AA | BB | AA | AA | **5 | Present Invention |
| 5 | Absent | [symbol] | BB | AA | AA | BB | **5 | Present Invention |
| 6 | Absent | 93.6 | CC | BB | AA | AA | **5 | Present Invention |
| 7 | Absent | [symbol] | BB | — | BB | AA | Water-repellent | Present Invention |
| | | | | | | | Functional Film | |
| 8 | Absent | [symbol] | BB | AA | AA | BB | **5 | Present Invention |
| 9 | Absent | 93.9 | BB | AA | AA | BB | **5 | Present Invention |
| 10 | Absent | 94.8 | BB | — | AA | AA | Anti-reflective | Present Invention |
| | | | | | | | Functional Film | |
| 11 | Absent | [symbol] | BB | AA | AA | BB | **5 | Present Invention |
| 12 | Absent | [symbol] | BB | AA | AA | CC | *Anti-fog | Present Invention |
| | | | | | | | Functional Film | |
| 13 | Absent | 94.2 | BB | AA | AA | AA | *Anti-fog | Present Invention |
| | | | | | | | Functional Film | |
| 14 | Absent | 93.4 | AA | BB | AA | AA | **5 | Present Invention |
| 15 | Absent | 86 | CC | CC | DD | DD | **5 | Comparative |
| | | | | | | | | Example |

*1: Functional Film
*2: Solubility of Particle containing layer in Water [g/mL] (20° C.)
*3: Method of Forming Particle Containing Layer
*4: Method of Forming Coating Layer
*5: Average Roughness of Burns [nm]
*6: Photocatalytic Layer
*7: Total Transmittance (%)
*8: Reflectance
**1: Super White Glass
**2: Resistance Heating Deposition
**3: SiO₂/SC100
**4: E [symbol] Deposition
**5: [symbol] Functional Film [symbol]
indicates data missing or illegible when filed

In Table I, the items “Particle Containing Layer,” “Solubility of Particle Containing Layer in Water,” and “Method of Forming Particle Containing Layer” relate to the particle containing layer formed directly on the photocatalytic layer. However, for functional film 12 (FIG. 17A and FIG. 17B) and functional film 13 (FIG. 18A and FIG. 18B), these items relate not only to the particle containing layer formed directly on the photocatalytic layer but also to the particle containing layer formed directly on on the first stacked structure K.

In Table I, “EB deposition” refers to electron beam vapor deposition.

As shown in the above results, the functional films of the present invention had superior hydrophilicity and photocatalytic effect under high temperature and high humidity environments compared to the functional film of the comparative example. It is also recognized that the functional films of the present invention is superior in rub resistance and reflectance compared to the functional film of the comparative example. Therefore, it can be said that the functional film of the present invention has improved properties.

Although one or more embodiments of the present invention have been described and illustrated in detail, the disclosed embodiments are made for purposes of not limitation but illustration and example only. The scope of the present invention should be interpreted by terms of the appended claims.

What is claimed is:

1. A functional film provided on a base material and having a fine uneven structure on a surface of the functional film, comprising:
a coating that is a coating film or a coating layer of the fine uneven structure, the coating being on a surface of the base material or a constituent layer and covering at least a bumpy portion or an entire surface of the base material, wherein
the fine uneven structure includes bumps and dents whose mutual positional relationship and shape have randomness with no regularity in terms of identity or periodicity and does not generate diffracted light.

2. A functional film provided on a base material and having a fine uneven structure on a surface of the functional film, comprising:
at least one uneven layer; and
a coating that is a coating layer on the uneven layer.

3. The functional film according to claim 2, wherein
the fine uneven structure includes bumps and dents whose mutual positional relationship and shape have randomness with no regularity in terms of identity or periodicity and does not generate diffracted light.

4. The functional film according to claim 1, wherein,
the fine uneven structure has an arithmetic average roughness Ra in a range of 2 to 50 nm,
the maximum height of the bumps is in a range of 10 to 500 nm, and
the average diameter of the bumps is in a range of 10 to 1000 nm.

5. The functional film according to claim 1, wherein
the coating is a dry-processed layer.

6. The functional film according to claim 1, wherein
the bumpy portion is a dry-processed layer.

7. The functional film according to claim 1, comprising
at least one compound that has a solubility in water at 20° C. of 0.5 g/100 mL or more.

8. The functional film according to claim 1, comprising
an inorganic salt in a part of the functional film.

9. The functional film according to claim 1, comprising
an alkali metal salt or alkaline earth metal salt in a part of the functional film.

10. The functional film according to claim 1, wherein
the fine uneven structure has a gap between bumps and dents adjacent to each other, the gap having a size that allows active chemical species generated by a photocatalyst reaction to pass through the gap.

11. The functional film according to claim 1, comprising
a photocatalytic layer between the base material and the bumpy portion.

12. The functional film according to claim 1, comprising
a photocatalytic layer that includes TiO₂ as a main component.

13. The functional film according to claim 1, comprising:
a reflectance adjustment layer between the base material and the bumpy portion, and
a photocatalytic layer between the base material and the bumpy portion; wherein
the coating is hydrophilic.

14. The functional film according to claim 1, wherein
the coating includes SiO₂ as a main component.

15. The functional film according to claim 1, wherein
the bumpy portion is formed by etching.

16. The functional film according to claim 1, wherein
the bumpy portion includes a particle containing layer and an intermediate layer, the particle containing layer having an uneven structure, and the intermediate layer adjusting shapes of particles of the particle containing layer, and
the base material, the intermediate layer, and the particle containing layer are arranged in this order.

17. The functional film according to claim 16, wherein
the intermediate layer has dents that are formed by etching.

18. The functional film according to claim 1, wherein
total transmittance of the functional film is 70% or more.

19. A production method of the functional film according to claim 1, comprising:
forming an unevenness unformed layer on the base material by a dry process.

20. The production method according to claim 19, comprising:
forming the bumpy portion by exposure of the base material on which the unevenness unformed layer has been formed to an environment including moisture.

21. The production method according to claim 20, comprising:
forming the coating by a dry process on the bumpy portion.

22. The production method according to claim 19, comprising:
after forming a layer of the functional film, storing the functional film in an high temperature and high humidity environment, thereby reducing an anionic component in the functional film.

23. The production method according to claim 19, comprising:
after forming a layer of the functional film, exposing the functional film to an environment containing an etching gas, thereby adjusting a size of a gap through which active chemical species generated by a photocatalyst reaction pass.

24. The functional film according to claim 3, wherein,
the fine uneven structure has an arithmetic average roughness Ra in a range of 2 to 50 nm,
the maximum height of the bumps is in a range of 10 to 500 nm, and
the average diameter of the bumps is in a range of 10 to 1000 nm.

25. The functional film according to claim 2, wherein
the coating is a dry-processed layer.

26. The functional film according to claim 2, wherein
the uneven layer is a dry-processed layer.

27. The functional film according to claim 2, comprising
at least one compound that has a solubility in water at 20° C. of 0.5 g/100 mL or more.

28. The functional film according to claim 2, comprising
an inorganic salt in a part of the functional film.

29. The functional film according to claim 2, comprising
an alkali metal salt or alkaline earth metal salt in a part of the functional film.

30. The functional film according to claim 2, wherein
the fine uneven structure has a gap between bumps and dents adjacent to each other, the gap having a size that allows active chemical species generated by a photocatalyst reaction to pass through the gap.

31. The functional film according to claim 2, comprising
a photocatalytic layer between the base material and the uneven layer.

32. The functional film according to claim 2, comprising
a photocatalytic layer that includes TiO₂ as a main component.

33. The functional film according to claim 2, comprising:
a reflectance adjustment layer between the base material and the uneven layer; and
a photocatalytic layer between the base material and the uneven layer, wherein
the coating is hydrophilic.

34. The functional film according to claim 2, wherein
the coating includes SiO₂ as a main component.

35. The functional film according to claim 2, wherein
the uneven layer is formed by etching.

36. The functional film according to claim 2, wherein
the uneven layer includes a particle containing layer and an intermediate layer, the particle containing layer having an uneven structure, and the intermediate layer adjusting shapes of particles of the particle containing layer, and
the base material, the intermediate layer, and the particle containing layer are arranged in this order.

37. The functional film according to claim 36, wherein
the intermediate layer has dents that are formed by etching.

38. The functional film according to claim 2, wherein
total transmittance of the functional film is 70% or more.

39. A production method of the functional film according to claim 2, comprising:
forming an unevenness unformed layer on the base material by a dry process.

40. The production method according to claim 39, comprising:
forming the uneven layer by exposure of the base material on which the unevenness unformed layer has been formed to an environment including moisture.

41. The production method according to claim 40, comprising:
forming the coating by a dry process on the uneven layer.

42. The production method according to claim 39, comprising:
after forming a layer of the functional film, storing the functional film in an high temperature and high humidity environment, thereby reducing an anionic component in the functional film.

43. The production method according to claim 39, comprising:
after forming a layer of the functional film, exposing the functional film to an environment containing an etching gas, thereby adjusting a size of a gap through which active chemical species generated by a photocatalyst reaction pass.
